(19) United States
(12) Patent Application Publication
(10) Pub. No.: US 2026/0013293 A1
(43) Pub. Date: Jan. 8, 2026

(54) Display Apparatus

(71) Applicant: LG Display Co., Ltd., Seoul (KR)

(72) Inventors: JinYoung Kim, Gumi-si (KR); DongGeun Bae, Goyang-si (KR)

(21) Appl. No.: 19/221,019

(22) Filed: May 28, 2025

(30) Foreign Application Priority Data
Jul. 2, 2024 (KR) 10-2024-0086886

(51) Int. Cl. H10H 29/37; H01L 25/16; H10H 29/41; H10H 29/49

(52) U.S. Cl. CPC H10H 29/37; H01L 25/167; H10H 29/41; H10H 29/49

(57) ABSTRACT

Provided is a display apparatus. The display apparatus comprises a substrate comprising a display area comprising a plurality of pixels, and a non-display area, one or more pixel drive circuits disposed on the substrate, a plurality of insulation layers disposed on the substrate, a plurality of banks on which the plurality of pixels is disposed on the plurality of insulation layers and a plurality of micro-LEDs disposed on the plurality of banks, wherein the plurality of pixels each comprise first subpixel and second subpixel sequentially disposed in a first direction in a first column and a third subpixel disposed in a second column.

### CROSS-REFERENCE TO RELATED APPLICATION

This application claims the priority of Republic of Korea Patent Application No. 10-2024-0086886 filed on Jul. 2, 2024, which is hereby incorporated by reference in its entirety.

### FIELD

The present disclosure relates to an apparatus and particularly to, for example, without limitation, a display apparatus.

### DESCRIPTION OF THE RELATED ART

A display apparatus is applied to various electronic apparatuses such as televisions (TVs), mobile phones, laptops, and tablets.

The display apparatus includes an organic light emitting display (OLED) apparatus that emits light by itself, a liquid crystal display (LCD) apparatus that requires a separate light source, etc.

Recently, the display apparatus including a light emitting diode (LED) is attracting attention as a next-generation display apparatus. Since the light emitting diode is made of an inorganic material rather than an organic material, the light emitting diode may have a fast-lighting speed and excellent light emitting efficiency, and may display a high brightness image, compared to the liquid crystal display apparatus or the organic light emitting display apparatus.

### SUMMARY

An object to be achieved by the present specification is to provide a display apparatus in which intervals between a plurality of subpixels are reduced by reducing intervals between banks in which micro-LEDs are disposed.

Another object to be achieved by the present specification is to provide a high-resolution display apparatus by reducing intervals between a plurality of subpixels.

Objects of the present disclosure are not limited to the above-mentioned objects, and other objects, which are not mentioned above, can be clearly understood by those skilled in the art from the following descriptions.

A display apparatus according to an exemplary embodiment of the present disclosure comprises a substrate comprising a display area comprising a plurality of pixels, and a non-display area, one or more pixel drive circuits disposed on the substrate, a plurality of insulation layers disposed on the substrate, a plurality of banks on which the plurality of pixels is disposed on the plurality of insulation layers and a plurality of micro-LEDs disposed on the plurality of banks, wherein the plurality of pixels each comprise first subpixel and second subpixel sequentially disposed in a first direction in a first column and a third subpixel disposed in a second column.

A display apparatus according to another exemplary embodiment of the present disclosure comprises a substrate, one or more pixel drive circuits disposed on the substrate, a plurality of insulation layers disposed on the pixel drive circuit, a plurality of banks disposed on the plurality of insulation layers and a plurality of micro-LEDs disposed on the plurality of banks and electrically connected to the pixel drive circuit, wherein some of the plurality of banks are different in long axis directions from some of the other banks.

According to the present specification, it is possible to reduce the pitch of the pixel.

According to the present specification, it is possible to improve the degree of integration of the pixel of the display apparatus.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an embodiment of the present specification;

FIG. 2 is a top plan view of the display apparatus according to an embodiment of the present specification;

FIG. 3 is an enlarged view of the display apparatus according to an embodiment of the present specification;

FIG. 4 is a view illustrating a circuit structure according to an embodiment of the present specification;

FIG. 5 is a top plan view of the display apparatus according to an embodiment of the present specification;

FIG. 6 is a top plan view of the display apparatus according to an embodiment of the present specification;

FIG. 7 is a top plan view of the display apparatus according to an embodiment of the present specification;

FIG. 8A is a cross-sectional view taken along line A-A′ in FIG. 5 according to an embodiment of the present specification;

FIG. 8B is a cross-sectional view taken along line B-B′ in FIG. 5 according to an embodiment of the present specification;

FIG. 9 is a cross-sectional view taken along line C-C′ in FIG. 3 according to an embodiment of the present specification;

FIG. 10 is a cross-sectional view of the display apparatus according to an embodiment of the present specification;

FIG. 11 is a top plan view of a display apparatus according to another embodiment of the present specification;

FIG. 12 is a top plan view of a display apparatus according to still another embodiment of the present specification;

FIG. 13A is a cross-sectional view taken along line D-D′ in FIG. 12 according to an embodiment of the present specification;

FIG. 13B is a cross-sectional view taken along line E-E′ in FIG. 12 according to an embodiment of the present specification; and

FIGS. 14 to 17 are views illustrating devices to which the display apparatus according to the embodiments of the present specification are applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When the relation of a time sequential order is described using the terms such as “after”, “continuously to”, “next to”, and “before”, the order may not be continuous unless the terms are used with the term “immediately” or “directly”.

Although the terms first, second, or the like are used to describe various components, these components are not limited by these terms. These terms are only used to distinguish one component from another. Thus, a first component referred to below may also be a second component within the technical scope of the present disclosure.

In describing components of the present disclosure, terms such as first, second, A, B, (a), or (b) may be used. These terms are only intended to distinguish the component from other components, and the nature, order, sequence, or number of the components are not limited by the terms.

When a component is described as being “connected”, “coupled”, “joined”, or “attached” to another component, it should be understood that that the component can be directly connected, coupled, joined, or attached to that other component, but that other components may also be interposed between the components which can be indirectly connected, coupled, joined, or attached, unless otherwise expressly stated.

When a component or layer is described as “contacting” or “overlapping” another component or layer, it should be understood that the component or layer may directly contact or overlap the other component or layer, but that other components may also be interposed between the components that may indirectly contact or overlap each other, unless specifically stated otherwise.

“At least one” should be understood to include any combination of one or more of the associated components. For example, “at least one of the first, second, and third components” could be understood to include any combination of two or more of the first, second, and third components, as well as the first, second, or third components.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

A “first direction”, “second direction”, “third direction”, “X-axis direction”, “Y-axis direction” and “Z-axis direction” should not be interpreted as merely geometric relationships in which the relationship between them is perpendicular to each other, but may mean a broader directionality within the scope in which the configuration of the present disclosure can function functionally.

The features of various embodiments of the present disclosure can be partially or entirely adhered to or combined with each other and can be interlocked and operated in technically various ways, and the embodiments can be carried out independently of or in association with each other.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Hereinafter, a display apparatus according to exemplary embodiments of the present disclosure will be described in detail with reference to accompanying drawings.

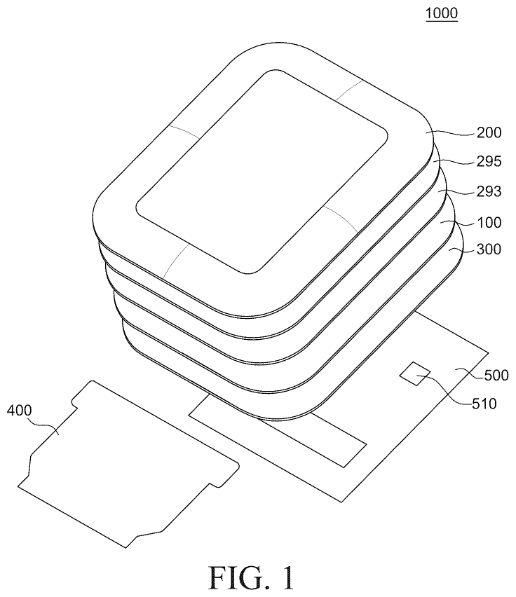

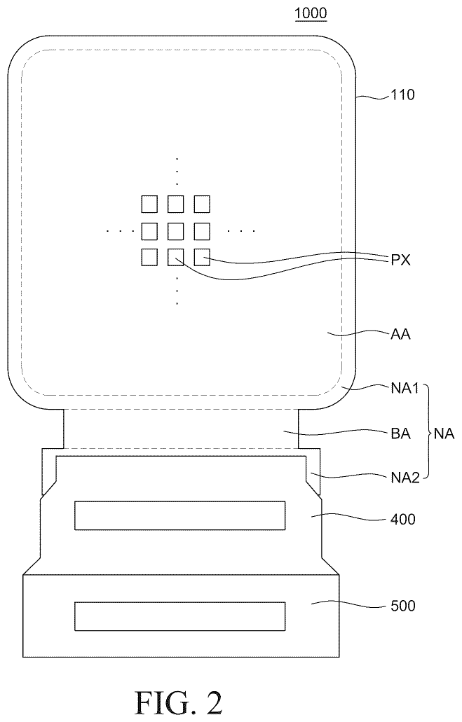

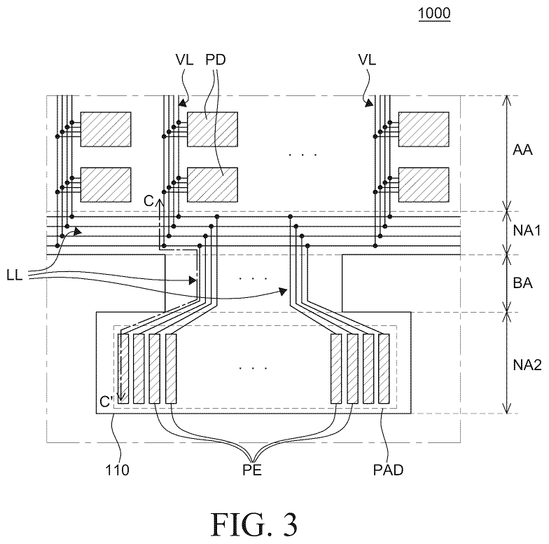

FIG. 1 is a perspective view illustrating a display apparatus according to an embodiment of the present specification. FIG. 2 is a top plan view of the display apparatus according to an embodiment of the present specification. FIG. 3 is an enlarged view of the display apparatus according to an embodiment of the present specification.

With reference to FIGS. 1 to 3, a display apparatus 1000 according to an embodiment of the present specification may include a display panel 100, a polarizing layer 293, a bonding layer 295, a cover member 200, a support substrate 300, a flexible circuit board 400, and a printed circuit board 500.

For example, the display panel 100 of the display apparatus 1000 may include a substrate 110. The substrate 110 may be a member configured to support other constituent elements of the display apparatus 1000. The substrate 110 may be made of an insulating material. For example, the substrate 110 may be made of glass, resin, or the like. In addition, the substrate 110 may be made of a material having flexibility. For example, the substrate 110 may be made of a plastic material, such as polyimide (PI), having flexibility. However, the embodiments of the present specification are not limited thereto.

The display panel 100 may implement information, videos, and/or images to be provided to a user. For example, the display panel 100 may include a display area AA and a non-display area NA. For example, the substrate 110 may include the display area AA and the non-display area NA. The display area AA and the non-display area NA may not be described as being limited to the substrate 110, but the display area AA and the non-display area NA may be described for the entire display apparatus 1000.

The display area AA may be an area in which images are displayed. The display area AA may include a plurality of pixels PX. The plurality of pixels PX may each include a plurality of subpixels. A plurality of micro-LEDs may be respectively disposed in the plurality of subpixels. The plurality of micro-LEDs may be differently configured in accordance with the type of display apparatus 1000. For example, in case that the display apparatus 1000 is an inorganic light-emitting display apparatus, the micro-LED may be a light-emitting diode (LED), a micro-light-emitting diode (micro-LED), or a mini-light-emitting diode (LED). However, the embodiments of the present specification are not limited thereto.

The non-display area NA may be an area in which no image is displayed. Various lines and circuits for operating the plurality of pixels PX in the display area AA may be disposed in the non-display area NA. For example, various types of lines and drive circuits may be mounted in the non-display area NA, and a pad part PAD, to which an integrated circuit, a printed circuit, and the like are connected, may be disposed. However, the embodiments of the present specification are not limited thereto.

For example, the drive circuits may be a data drive circuit and/or a gate drive circuit. However, the embodiments of the present specification are not limited thereto. Lines for supplying control signals for controlling the drive circuits may be disposed. For example, the control signals may include various types of timing signals including clock signals, input data enable signals, and synchronizing signals. However, the embodiments of the present specification are not limited thereto. The control signal may be received through the pad part PAD. For example, link lines LL for transmitting signals may be disposed in the non-display area NA. For example, drive components, such as the flexible circuit board 400 and the printed circuit board 500, may be connected to the pad part PAD.

According to the present specification, the non-display area NA may include a first non-display area NA1, a bending area BA, and a second non-display area NA2. For example, the first non-display area NA1 may be an area that surrounds at least a part of the display area AA. The bending area BA may be a bendable area extending from at least any one of a plurality of sides of the first non-display area NA1. The second non-display area NA2 may be an area extending from the bending area BA, and the pad part PAD may be disposed in the second non-display area NA2. For example, the bending area BA may be in a curved state, and the remaining area of the substrate 110, except for the bending area BA, may be in a flat state. In this case, as the bending area BA is curved, the second non-display area NA2 may be positioned on a rear surface of the display area AA. However, the embodiments of the present specification are not limited thereto.

The display area AA of the substrate 110 or the display apparatus 1000 may have various shapes in accordance with the design of the display apparatus 1000. For example, the display area AA may have a rectangular shape having four corners with round shapes. However, the embodiments of the present specification are not limited thereto. In another example, the display area AA may have a circular shape or a rectangular shape having four corners with right-angled shapes. However, the embodiments of the present specification are not limited thereto.

According to the present specification, a width of the second non-display area NA2 in which a plurality of pad electrodes PE are disposed may be larger than a width of the bending area BA in which only the plurality of link lines LL are disposed. In addition, a width of the display area AA in which the plurality of subpixels are disposed may be larger than a width of the bending area BA in which the plurality of link lines LL are disposed. The drawing illustrates that the width of the bending area BA may be smaller than a width of another area of the substrate 110. However, the shape of the substrate 110 including the bending area BA is illustrative, and the embodiments of the present specification are not limited thereto.

With reference to FIG. 3, a plurality of pixel drive circuits PD may be disposed in the display area AA. The plurality of pixel drive circuits PD may be circuits for operating the micro-LEDs of the plurality of subpixels. The plurality of pixel drive circuits PD may each include a plurality of transistors including a driving transistor, and a plurality of storage capacitors. The plurality of pixel drive circuits PD may control light-emitting operations of the plurality of micro-LEDs by supplying control signals, power, and drive currents to the micro-LEDs of the plurality of subpixels. For example, the pixel drive circuit PD may include a power line, and a signal line for controlling light-emitting on/off operations and/or light emission time of the micro-LED. For example, the plurality of pixel drive circuits PD may be operation drivers manufactured on a semiconductor substrate by using a metal-oxide-silicon field effect transistor (MOSFET) manufacturing process. However, the embodiments of the present specification are not limited thereto. The operation driver may include the plurality of pixel drive circuits PD and operate the plurality of subpixels.

With reference to FIG. 1 together, the flexible circuit board 400 and the printed circuit board 500 may be disposed below the display panel 100. The flexible circuit board 400 and the printed circuit board 500 may be disposed at least at one side edge of the display panel 100. However, the embodiments of the present specification are not limited thereto. One side of the flexible circuit board 400 may be attached to the display panel 100, and the other side of the flexible circuit board 400 may be attached to the printed circuit board 500. However, the embodiments of the present specification are not limited thereto. The flexible circuit board 400 may be a flexible film. However, the embodiments of the present specification are not limited thereto.

The pad part PAD including the plurality of pad electrodes PE may be disposed in the second non-display area NA2. The drive components including one or more flexible circuit boards (or flexible films) 400 and the printed circuit board 500 may be attached or bonded to the pad part PAD. The plurality of pad electrodes PE of the pad part PAD may be electrically connected to one or more flexible circuit boards (or flexible films) 400 and transmit various types of signals (or power) to the plurality of pixel drive circuits PD in the display area AA from the printed circuit board 500 and the flexible circuit board (or flexible film) 400.

The flexible circuit board (or flexible film) 400 may be a film having various types of components disposed on a base film having flexibility. For example, a drive integrated circuit (IC), such as a gate driver IC or a data driver IC, may be disposed on the flexible circuit board (or flexible film) 400. However, the embodiments of the present specification are not limited thereto. The drive IC may be a component configured to process data and driving signals for displaying images. The drive IC may be disposed in ways such as a chip-on-glass (COG) method, a chip-on-film (COF) method, or a tape carrier package (TCP) method depending on how the drive IC is mounted. However, the embodiments of the present specification are not limited thereto. The flexible circuit board (or flexible film) 400 may be attached or bonded to the plurality of pad electrodes PE by means of a conductive bonding layer. However, the embodiments of the present specification are not limited thereto.

The printed circuit board 500 may be a component electrically connected to one or more flexible circuit boards (or flexible films) 400 and configured to supply a signal to the drive IC. The printed circuit board 500 may be disposed at one side of the flexible circuit board (or flexible film) 400 and electrically connected to the flexible circuit board (or flexible film) 400. Various types of components for supplying various signals to the drive IC may be disposed on the printed circuit board 500. For example, various components, such as a timing controller, a power source, a memory, or a processor, may be disposed on the printed circuit board 500. For example, the printed circuit board 500 may include a power management integrated circuit (PMIC). However, the embodiments of the present specification are not limited thereto.

The printed circuit board 500 may include at least one hole 510. However, the embodiments of the present specification are not limited thereto. Internal components may be disposed in an area corresponding to at least one hole 510 and detect ambient light, a temperature, or the like that may be provided to the plurality of sensors. For example, the internal components may include an ambient light sensor (ALS), a temperature sensor, or the like. However, the embodiments of the present specification are not limited thereto. For example, the hole 510 may be a transmission hole or the like. However, the embodiments of the present specification are not limited thereto.

With reference to FIG. 1, the polarizing layer 293 may be disposed on the display panel 100. The polarizing layer 293 may suppress or reduce a situation in which light generated from the external light source is introduced into the display panel 100 and affects the micro-LED or the like.

The cover member 200 may be disposed on the polarizing layer 293. The cover member 200 may be a member for protecting the display panel 100. The bonding layer 295 may be disposed between the polarizing layer 293 and the cover member 200. The cover member 200 may be attached to the display panel 100 by using the bonding layer 295. The bonding layer 295 may include an optically clear adhesive (OCA), an optically clear resin (OCR), a pressure-sensitive adhesive (PSA), or the like. However, the embodiments of the present specification are not limited thereto.

The support substrate 300 may be disposed between the display panel 100 and the printed circuit board 500. The support substrate 300 may reinforce the rigidity of the display panel 100. The support substrate 300 may be a backplate. However, the embodiments of the present specification are not limited thereto.

With reference to FIGS. 1 to 3, the plurality of link lines LL may be disposed in the non-display area NA. The plurality of link lines LL may be lines configured to transmit various types of signals to the display area AA from one or more flexible circuit boards (or flexible films) 400 and the printed circuit board 500. The plurality of link lines LL may extend from the plurality of pad electrodes PE of the second non-display area NA2 toward the bending area BA and the first non-display area NA1 and be electrically connected to a plurality of drive lines VL in the display area AA. The plurality of pixel drive circuits PD may operate by receiving signals from one or more flexible circuit boards (or flexible films) 400 and the printed circuit board 500 through the drive lines VL in the display area AA and the link lines LL in the non-display area NA.

For example, the plurality of drive lines VL may be lines configured to transmit signals, which are outputted from the flexible circuit board (or flexible film) 400 and the printed circuit board 500, to the plurality of pixel drive circuits PD together with the plurality of link lines LL. The plurality of drive lines VL may be disposed in the display area AA and respectively electrically connected to the plurality of pixel drive circuits PD. The plurality of drive lines VL may extend from the display area AA toward the non-display area NA and be electrically connected to the plurality of link lines LL. Therefore, the signals outputted from the flexible circuit board (or flexible film) 400 and the printed circuit board 500 may be transmitted to the plurality of pixel drive circuits PD through the plurality of link lines LL and the plurality of drive lines VL.

When the bending area BA is bent, the plurality of link lines LL may also be partially bent. Stress may be concentrated on a part of the bent link line LL, and therefore, the link line LL may crack. Therefore, the plurality of link lines LL may be made of an electrically conductive material that is excellent in flexibility in order to reduce the occurrence of a crack when the bending area BA is bent. For example, the plurality of link lines LL may be made of an electrically conductive material, such as gold (Au), silver (Ag), or aluminum (Al), that is excellent in flexibility. However, the embodiments of the present specification are not limited thereto. In addition, the plurality of link lines LL may be made of one of various electrically conductive materials used for the display area AA. For example, the plurality of link lines LL may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present specification are not limited thereto. The plurality of link lines LL may have a multilayer structure including various electrically conductive material. For example, the plurality of link lines LL may have a triple layer structure made of titanium (Ti), aluminum (Al), and titanium (Ti). However, the embodiments of the present specification are not limited thereto.

The plurality of link lines LL may have various shapes to reduce stress. At least a part of each of the plurality of link lines LL disposed in the bending area BA may extend in a direction identical to an extension direction of the bending area BA or extend in a direction different from the extension direction of the bending area BA to reduce stress. For example, in case that the bending area BA extends in one direction from the first non-display area NA1 toward the second non-display area NA2, at least a part of the link line LL disposed in the bending area BA may extend in a direction inclined with respect to one direction. In another example, at least a part of each of the plurality of link lines LL may have patterns with various shapes. For example, at least a part of each of the plurality of link lines LL disposed in the bending area BA may have a shape in which conductive patterns are repeatedly disposed and have at least one of a diamond shape, a rhombic shape, a trapezoidal wave shape, a triangular wave shape, a serrated wave shape, a sine wave shape, a circular shape, and an omega (Ω) shape. However, the embodiments of the present specification are not limited thereto. Therefore, in order to minimize stress concentrated on the plurality of link lines LL and minimize the occurrence of a crack caused by the stress, the plurality of link lines LL may have various shapes including the above-mentioned shapes. However, the embodiments of the present specification are not limited thereto.

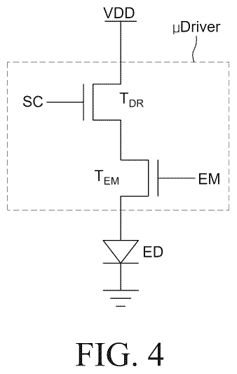

FIG. 4 is a view illustrating a circuit structure according to an embodiment of the present specification.

The pixel drive circuit PD may include a micro-driver Driver. A micro-LED ED may be electrically connected to the micro-driver Driver of the pixel drive circuit PD and operated. FIG. 4 illustrates that one micro-LED ED is connected to the micro-driver μDriver. However, the present disclosure is not limited thereto. For example, eight micro-LEDs ED may be connected to one micro-driver μDriver. In another example, sixteen micro-LEDs ED may be connected to one micro-driver Driver, or thirty-two micro-LEDs ED or sixty-four micro-LEDs ED may be simultaneously connected to one micro-driver μDriver.

One micro-driver μDriver may include a driving transistor T_{DR} and a light-emitting transistor T_{EM}. However, the embodiments of the present specification are not limited thereto.

For example, a high-potential power voltage VDD may be applied to a first electrode of the driving transistor T_{DR}, a first electrode of the light-emitting transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} may be direct current power, and a fixed reference voltage may be applied for each frame. However, the embodiments of the present specification are not limited thereto.

The second electrode of the driving transistor T_{DR} may be connected to the first electrode of the light-emitting transistor T_{EM}, the micro-LED ED may be connected to a second electrode of the light-emitting transistor T_{EM}, and a light emission signal EM may be applied to a gate electrode of the light-emitting transistor T_{EM}. The light emission signal EM applied to the gate electrode of the light-emitting transistor T_{EM} may be a pulse width modulation signal that changes for each frame. However, the embodiments of the present specification are not limited thereto.

A first electrode of the micro-LED ED may be connected to the second electrode of the light-emitting transistor T_{EM}, and a second electrode of the micro-LED ED may be connected to the ground. For example, the first electrode may be an anode electrode, and the second electrode may be a cathode electrode. However, the embodiments of the present specification are not limited thereto.

The driving transistor T_{DR} and the light-emitting transistor T_{EM} may each be an n-type transistor or a p-type transistor.

The driving transistor T_{DR} may be turned on by the scan signal SC applied from a timing controller T-CON to the micro-driver μDriver, and the light-emitting transistor T_{EM} may be turned on by the light emission signal EM. Therefore, the drive current is applied to the micro-LED ED via the driving transistor T_{DR} and the light-emitting transistor T_{EM} by the high-potential power voltage VDD applied to the first electrode of the driving transistor T_{DR}, such that the micro-LED ED may emit light.

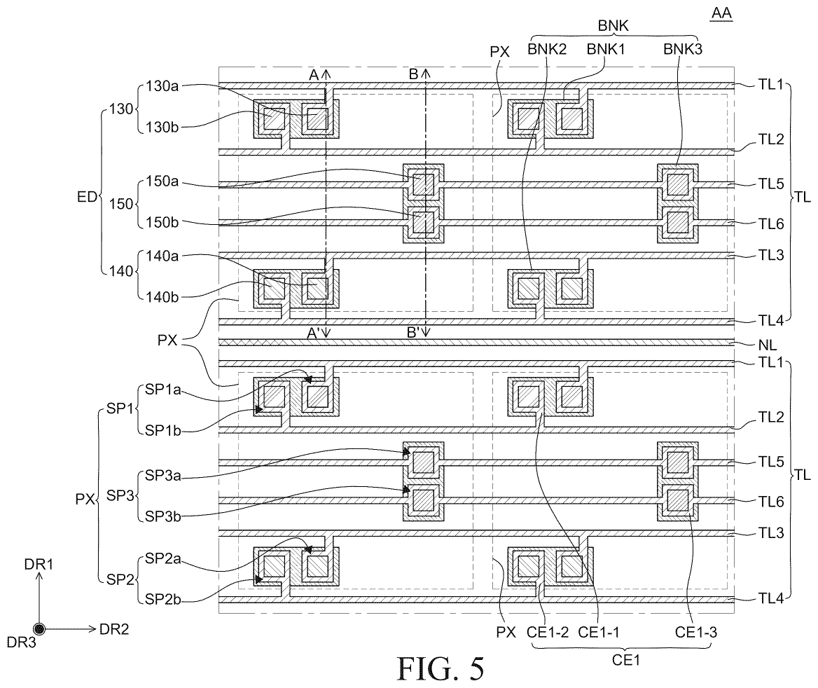

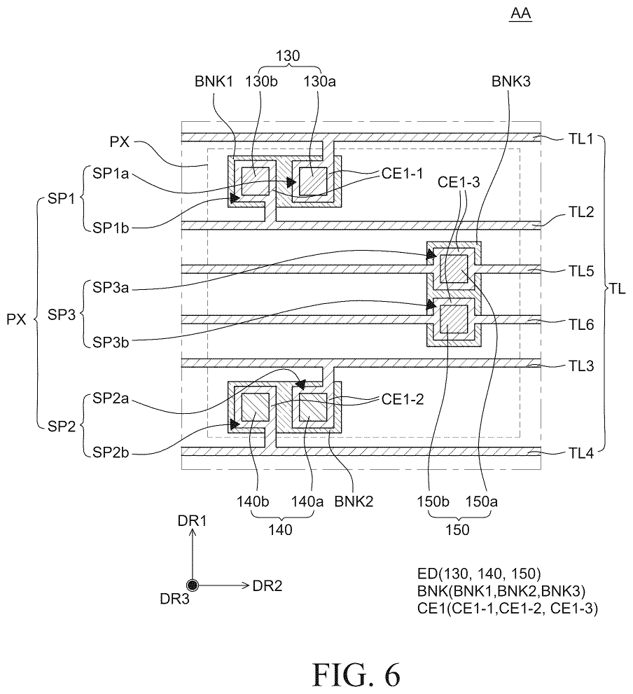

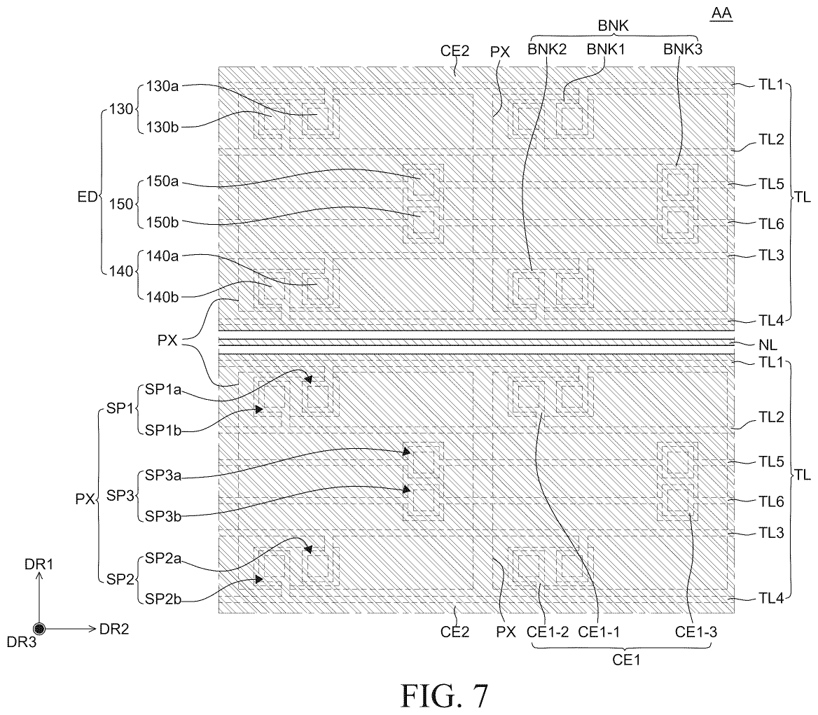

FIGS. 5 to 7 are top plan views of the display apparatus according to an embodiment of the present specification. For example, FIG. 5 is an enlarged top plan view of a display area including a plurality of pixels according to an embodiment of the present specification. For example, FIG. 6 is an enlarged top plan view of a display area including a single pixel according to an embodiment of the present specification. For example, FIG. 7 is an enlarged top plan view of a display area including a plurality of pixels according to an embodiment of the present specification. FIGS. 5 and 6 illustrate a plurality of signal lines TL, a plurality of communication lines NL, a plurality of first electrodes CE1, a plurality of banks BNK, and a plurality of micro-LEDs ED. However, the embodiments of the present specification are not limited thereto. FIG. 7 is an enlarged top plan view illustrating a state in which a plurality of second electrodes CE2 is additionally disposed in FIG. 5.

With reference to FIGS. 5 and 6, the plurality of pixels PX including the plurality of subpixels may be disposed in the display area AA. The plurality of subpixels may each include the micro-LED ED and emit light independently. The plurality of subpixels may be disposed in a plurality of rows and a plurality of columns while defining a matrix shape. However, the embodiments of the present specification are not limited thereto.

The plurality of subpixels may include a first subpixel SP1, a second subpixel SP2, and a third subpixel SP3. For example, any one of the first subpixel SP1, the second subpixel SP2, and the third subpixel SP3 may be a red subpixel, another subpixel may be a green subpixel, and the remaining subpixel may be a blue subpixel. The types of subpixels are illustrative. However, the embodiments of the present specification are not limited thereto.

The plurality of subpixels constituting one pixel PX may be variously arranged. For example, in one pixel PX, the first subpixel SP1 and the second subpixel SP2 may be disposed sequentially in a first direction DR1. For example, the plurality of first subpixels SP1 and the plurality of second subpixels SP2 may be alternately disposed in a first column. The third subpixel SP3 may be disposed between the first subpixels SP1 adjacent to each other in a second direction DR2, and the third subpixel SP3 may be disposed between the second subpixels SP2 adjacent to each other in the second direction DR2. In this case, the third subpixels SP3 may be disposed in rows and columns different from those of the first subpixels SP1 and the second subpixels SP2. For example, the third subpixels SP3 may be disposed in a second column. In addition, the third subpixel SP3 may be disposed so as not to overlap the first subpixel SP1 and the second subpixel SP2 in the first direction DR1 and disposed so as not to overlap the first subpixel SP1 and the second subpixel SP2 in the second direction DR2. The number of and arrangement of the plurality of subpixels constituting one pixel PX are illustrative. However, the embodiments of the present specification are not limited thereto.

The plurality of pixels PX may each include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may include a first-first subpixel SP1a and a first-second subpixel SP1b. The pair of second subpixels SP2 may include a second-first subpixel SP2a and a second-second subpixel SP2b. The pair of third subpixels SP3 may include a third-first subpixel SP3a and a third-second subpixel SP3b. For example, one pixel PX may include the first-first subpixel SP1a, the first-second subpixel SP1b, the second-first subpixel SP2a, the second-second subpixel SP2b, the third-first subpixel SP3a, and the third-second subpixel SP3b. However, the embodiments of the present specification are not limited thereto.

In one pixel PX, the pair of first subpixels SP1 may be disposed in the same row, the pair of second subpixels SP2 may be disposed in the same row, and the pair of third subpixels SP3 may be disposed in the same column. For example, the first-first subpixel SP1a and the first-second subpixel SP1b may be arranged in the second direction DR2. The second-first subpixel SP2a and the second-second subpixel SP2b may be arranged in the second direction DR2. The third-first subpixel SP3a and the third-second subpixel SP3b may be arranged in the first direction DR1.

The plurality of signal lines TL may be disposed in areas between the plurality of subpixels. The plurality of signal lines TL may extend in a row direction between the plurality of subpixels. The plurality of signal lines TL may be lines configured to transmit an anode voltage from the pixel drive circuit PD to the plurality of subpixels. For example, the plurality of signal lines TL may be electrically connected to the plurality of pixel drive circuits PD and the first electrodes CE1 of the plurality of subpixels. The anode voltage outputted from the pixel drive circuit PD may be transmitted to the first electrodes CE1 of the plurality of subpixels through the plurality of signal lines TL. For example, the first electrode CE1 may be an electrode electrically connected to an anode electrode 134 of the micro-LED ED. Therefore, the anode voltage from the signal line TL may be transmitted to the anode electrode 134 of the micro-LED ED through the first electrode CE1.

Therefore, the structure of the display apparatus 1000 may be simplified by using the pixel drive circuit PD into which a plurality of pixel circuits are integrated instead of forming a plurality of transistors and a plurality of storage capacitors in the plurality of subpixels. In addition, because the circuits respectively disposed in the plurality of subpixels are integrated into one pixel drive circuit PD, the high-efficiency operation with low power consumption may be performed.

The plurality of signal lines TL may include first signal lines TL1, second signal lines TL2, third signal lines TL3, fourth signal lines TL4, fifth signal lines TL5, and sixth signal lines TL6.

The plurality of signal lines TL may each be disposed straight in the second direction DR2. The plurality of signal lines TL may be electrically connected to the subpixels disposed in the second direction DR2 among the plurality of subpixels. For example, the first signal line TL1 and the second signal line TL2 may each be electrically connected to the plurality of first subpixels SP1. The third signal line TL3 and the fourth signal line TL4 may each be electrically connected to the plurality of second subpixels SP2. The fifth signal line TL5 and the sixth signal line TL6 may each be electrically connected to the plurality of third subpixels SP3.

Therefore, the plurality of signal lines TL may be electrically connected to the micro-LEDs ED disposed in the second direction DR2 among the plurality of micro-LEDs ED. For example, the first signal line TL1 and the second signal line TL2 may each be electrically connected to a plurality of first micro-LEDs ED1. The third signal line TL3 and the fourth signal line TL4 may each be electrically connected to a plurality of second micro-LEDs ED2. The fifth signal line TL5 and the sixth signal line TL6 may each be electrically connected to a plurality of third micro-LEDs ED3.

The plurality of signal lines TL may be disposed to be spaced apart from one another in the first direction DR1. For example, the first signal line TL1, the second signal line TL2, the fifth signal line TL5, the sixth signal line TL6, the third signal line TL3, and the fourth signal line TL4 may be sequentially disposed in the first direction DR1.

Among the plurality of signal lines TL, the pair of signal lines TL may be disposed at two opposite sides of the pair of subpixels. For example, the first signal line TL1 may be disposed at one side of the pair of first subpixels SP1, and the second signal line TL2 may be disposed at another side of the pair of first subpixels SP1. For example, the first signal line TL1 and the second signal line TL2 may be disposed adjacent to each other with the first subpixel SP1 interposed therebetween in the first direction DR1. In addition, the first signal line TL1 may be disposed adjacent to the fourth signal line TL4 connected to the second subpixels SP2 that are the adjacent subpixels. In addition, the second signal line TL2 may be disposed adjacent to the fifth signal line TL5 connected to the third subpixels SP3 that are the adjacent subpixels.

The third signal line TL3 may be disposed at one side of the pair of second subpixels SP2, and the fourth signal line TL4 may be disposed at another side of the pair of second subpixels SP2. For example, the third signal line TL3 and the fourth signal line TL4 may be disposed adjacent to each other with the second subpixel SP2 interposed therebetween in the first direction DR1. In addition, the third signal line TL3 may be disposed adjacent to the sixth signal line TL6 connected to the third subpixels SP3 that are the adjacent subpixels. In addition, the fourth signal line TL4 may be disposed adjacent to the first signal line TL1 connected to the first subpixels SP1 that are the adjacent subpixels.

The fifth signal line TL5 may be disposed at one side of the pair of third subpixels SP3, and the sixth signal line TL6 may be disposed at another side of the pair of third subpixels SP3. For example, the fifth signal line TL5 and the sixth signal line TL6 may be disposed adjacent to each other in the first direction DR1. The fifth signal line TL5 may be disposed adjacent to the second signal line TL2 connected to the first subpixel SP1 that are the adjacent subpixels. In addition, the sixth signal line TL6 may be disposed adjacent to the third signal line TL3 connected to the second subpixels SP2 that are the adjacent subpixels.

Some of the plurality of signal lines TL may be respectively connected to the plurality of first electrodes CE1 extending in the first direction DR1. For example, among the plurality of signal lines TL, the first signal line TL1 and the second signal line TL2 may each be connected to the plurality of first subpixels SP1 through the plurality of first electrodes CE1 extending in the first direction DR1. For example, the first signal line TL1 may be electrically connected to one of the pair of first subpixels SP1, e.g., the first electrode CE1 of the first-first subpixel SP1a. The second signal line TL2 may be electrically connected to the remaining one of the pair of first subpixels SP1, e.g., the first electrode CE1 of the first-second subpixel SP1b.

The third signal line TL3 and the fourth signal line TL4 may each be connected to the plurality of second subpixels SP2 through the plurality of first electrodes CE1 extending in the first direction DR1. For example, the third signal line TL3 may be electrically connected to one of the pair of second subpixels SP2, e.g., the first electrode CE1 of the second-first subpixel SP2a. The fourth signal line TL4 may be electrically connected to the remaining one of the pair of second subpixels SP2, e.g., the first electrode CE1 of the second-second subpixel SP2b.

Some of the plurality of signal lines TL may be respectively connected to the plurality of first electrodes CE1 extending in the second direction DR2. Meanwhile, some of the plurality of signal lines TL may include a plurality of lines disposed alternately with the plurality of first electrodes CE1 in the second direction DR2. For example, the fifth signal line TL5 and the plurality of sixth signal lines TL6 may include a plurality of lines disposed to be spaced apart from one another with the plurality of first electrodes CE1 interposed between in the second direction DR2. In another example, the fifth signal line TL5 and the sixth signal line TL6 may include a plurality of lines disposed alternately with a plurality of third banks BNK3 in the second direction DR2. In this case, two opposite ends of each of the plurality of lines of the fifth signal line TL5 and the plurality of lines of the sixth signal line TL6 may be connected to two opposite ends of each of the plurality of first electrodes CE1 extending from the plurality of third banks BNK3 in the second direction DR2. For example, the fifth signal line TL5 may be electrically connected to one of the pair of third subpixels SP3, e.g., the first electrode CE1 of the third-first subpixel SP3a. The sixth signal line TL6 may be electrically connected to the remaining one of the pair of third subpixels SP3, e.g., the first electrode CE1 of the third-second subpixel SP3b.

The plurality of signal lines TL may be made of an electrically conductive material. For example, the plurality of signal lines TL may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present specification are not limited thereto. In another example, the plurality of signal lines TL may have a multilayer structure made of an electrically conductive material. For example, the plurality of signal lines TL may have a multilayer structure made of titanium (Ti), aluminum (Al), titanium (Ti), and indium tin oxide (ITO). However, the embodiments of the present specification are not limited thereto.

The plurality of communication lines NL may be disposed in areas between the plurality of pixels PX. The plurality of communication lines NL may be disposed to extend in the row direction in the areas between the plurality of pixels PX. The plurality of communication lines NL may be disposed in the areas between the plurality of second electrodes CE2 and may not overlap the plurality of second electrodes CE2. For example, the plurality of communication lines NL may be lines used for short-range communication such as near field communication (NFC). The plurality of communication lines NL may serve as antennas. For example, the plurality of communication lines NL may be a plurality of connection lines and the like. However, the embodiments of the present specification are not limited thereto.

According to the present specification, the bank BNK may be disposed in each of the plurality of subpixels. The plurality of banks BNK may have structures on which the plurality of micro-LEDs ED are seated. The plurality of banks BNK may guide positions of the plurality of micro-LEDs ED during the process of transferring the plurality of micro-LEDs ED to the display apparatus 1000. The plurality of micro-LEDs ED may be transferred onto the plurality of banks BNK during the process of transferring the plurality of micro-LEDs ED. The plurality of banks BNK may be bank patterns, structures, or the like. However, the embodiments of the present specification are not limited thereto.

The plurality of banks BNK may include a plurality of first banks BNK1, a plurality of second banks BNK2, and the plurality of third banks BNK3. The plurality of first banks BNK1 may be disposed to correspond to the plurality of first subpixels SP1, the plurality of second banks BNK2 may be disposed to correspond to the plurality of second subpixels SP2, and the plurality of third banks BNK3 may be disposed to correspond to the plurality of third subpixels SP3.

In one pixel PX, the first bank BNK1 and the second bank BNK2 may be sequentially disposed in the first direction DR1. For example, the plurality of first banks BNK1 and the plurality of second banks BNK2 may be alternately disposed in the first column. The plurality of third banks BNK3 may be sequentially disposed in the first direction DR1. For example, the third banks BNK3 may be disposed in the second column.

The plurality of first banks BNK1, the plurality of second banks BNK2, and the plurality of third banks BNK3 may be disposed to be spaced apart from one another. The plurality of first banks BNK1, the plurality of second banks BNK2, and the plurality of third banks BNK3 may be configured to be separated from one another. Therefore, the banks BNK of the first subpixel SP1, the second subpixel SP2, and the third subpixel SP3, to which the micro-LEDs ED configured to emit light beams with different colors are transferred, may be easily identified.

The plurality of banks BNK may include the banks BNK having different long axis directions. For example, the plurality of first banks BNK1 and the plurality of second banks BNK2 may have the same or substantially same long axis direction. In contrast, the long axis direction of the plurality of third banks BNK3 may be different from the long axis direction of the plurality of first banks BNK1 and the long axis direction of the plurality of second banks BNK2. With reference to FIGS. 5 to 7, the plurality of first banks BNK1 and the plurality of second banks BNK2 may each have a long axis in the second direction DR2 and a short axis in the first direction DR1. In contrast, the plurality of third banks BNK3 may each have a long axis in the first direction DR1 and a short axis in the second direction DR2.

Meanwhile, a distance between the first bank BNK1 and the second bank BNK2 may be longer than a length of the third bank BNK3 in the second direction DR2. For example, the distance between the first bank BNK1 and the second bank BNK2 may be longer than a long axis length of the third bank BNK. Therefore, the third bank BNK may not overlap the first bank BNK1 and the second bank BNK2 in the second direction DR2. In addition, the third bank BNK may not overlap the first bank BNK1 and the second bank BNK2 in the first direction DR1.

The pair of subpixels configured to emit light beams with the same color may be disposed on the plurality of banks BNK. Specifically, the pair of subpixels configured to emit light beams with the same color may be disposed in the long axis direction of the plurality of banks BNK. For example, the first-first subpixel SP1a and the first-second subpixel SP1b may be disposed in the second direction DR2 on each of the plurality of first banks BNK1. The second-first subpixel SP2a and the second-second subpixel SP2b may be disposed in the second direction DR2 on each of the plurality of second banks BNK2. The third-first subpixel SP3a and the third-second subpixel SP3b may be disposed in the first direction DR1 on each of the plurality of third banks BNK3.

Only one subpixel may be disposed on one bank BNK in consideration of designs such as transfer process requirements. For example, the bank BNK of the first-first subpixel SP1a and the bank BNK of the first-second subpixel SP1b may be spaced apart from each other or separated from each other. Further, the bank BNK of the second-first subpixel SP2a and the bank BNK of the second-second subpixel SP2b may be spaced apart from each other or separated from each other. The bank BNK of the third-first subpixel SP3a and the bank BNK of the third-second subpixel SP3b may be spaced apart from each other or separated from each other. However, the present specification is not limited thereto. The banks BNK may be variously formed. However, the embodiments of the present specification are not limited thereto.

For example, the plurality of banks BNK may made of an organic insulating material. The plurality of banks BNK may each be configured as a single layer or multilayer made of an organic insulating material. For example, the plurality of banks BNK may be made of photoresist, polyimide (PI), an acrylic material, or the like. However, the embodiments of the present specification are not limited thereto.

The plurality of first electrodes CE1 may be disposed in the plurality of subpixels. The plurality of first electrodes CE1 may be disposed on the plurality of banks BNK. For example, the plurality of first electrodes CE1 may be disposed on top surfaces and side surfaces of the plurality of banks BNK.

The plurality of first electrodes CE1 may include a plurality of first-first electrodes CE1-1, a plurality of first-second electrodes CE1-2, and a plurality of first-third electrodes CE1-3.

The plurality of first-first electrodes CE1-1 may be disposed on the plurality of first banks BNK1. The plurality of first-second electrodes CE1-2 may be disposed on the plurality of second banks BNK2. The plurality of first-third electrodes CE1-3 may be disposed on the plurality of third banks BNK3.

The plurality of first electrodes CE1 may include the first electrodes CE1 extending in different directions on the plurality of banks BNK. For example, the plurality of first-first electrodes CE1-1 may extend in the first direction DR1 on the plurality of first banks BNK1. The plurality of first-second electrodes CE1-2 may extend in the first direction DR1 on the plurality of second banks BNK2. The plurality of first-third electrodes CE1-3 may extend in the second direction DR2 on the plurality of third banks BNK3.

Some of the plurality of first electrodes CE1 may each cover one side surface of the bank BNK. For example, the plurality of first-first electrodes CE1-1 may each extend in one direction from a center of each of the plurality of first banks BNK1 and cover one side surface of each of the plurality of first banks BNK1. The plurality of first-second electrodes CE1-2 may each extend in one direction on each of the plurality of second banks BNK2 and cover one side surface of each of the plurality of second banks BNK2. Some of the other first electrodes CE1 may each cover two opposite surfaces of the bank BNK. The plurality of first-third electrodes CE1-3 may each extend in the opposite direction from a center of each of the plurality of third banks BNK3 and cover two opposite surfaces of each of the plurality of third banks BNK3 that face each other.

The first electrode CE1 may be electrically connected to one of the plurality of signal lines TL. At least a part of the first electrode CE1 may extend to the outside of the bank BNK and be electrically connected to the signal line TL closest to the first electrode CE1. For example, the first-first electrode CE1-1 connected to the first-first subpixel SP1a may extend in one direction on the first bank BNK1 and be electrically connected to the first signal line TL1, and the first-first electrode CE1-1 connected to the first-second subpixel SP1b may extend in the other direction on the first bank BNK1 and be electrically connected to the second signal line TL2. The first-second electrode CE1-2 connected to the second-first subpixel SP2a may extend in one direction on the second bank BNK2 and be electrically connected to the third signal line TL3, and the first-second electrode CE1-2 connected to the second-second subpixel SP2b may extend in the other direction on the second bank BNK2 and be electrically connected to the fourth signal line TL4. The first-third electrode CE1-3 connected to the third-first subpixel SP3a may extend in two opposite directions on the third bank BNK3 and be electrically connected to the fifth signal line TL5, and the first-third electrode CE1-3 connected to the third-second subpixel SP3b may extend in two opposite directions on the third bank BNK3 and be electrically connected to the sixth signal line TL6.

The plurality of first electrodes CE1 may each be electrically connected to the anode electrode 134 of the micro-LED ED and transmit the anode voltage from the pixel drive circuit PD to the micro-LED ED through the signal line TL. Different voltages may be applied to the first electrode CE1 of each of the plurality of subpixels in accordance with the displayed images. For example, different voltages may be applied to the first electrode CE1 of each of the plurality of subpixels. Therefore, the first electrode CE1 may be a pixel electrode. However, the embodiments of the present specification are not limited thereto.

The plurality of first electrodes CE1 may each be made of an electrically conductive material. For example, the plurality of first electrodes CE1 may be integrated with the plurality of signal lines TL. For example, the plurality of first electrodes CE1 may be made of the same or substantially same electrically conductive material as the plurality of signal lines TL. However, the embodiments of the present specification are not limited thereto. For example, the plurality of first electrodes CE1 may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present specification are not limited thereto. In another example, the first electrode CE1 may have a multilayer structure made of an electrically conductive material. For example, the plurality of first electrodes CE1 may each have a multilayer structure made of titanium (Ti), aluminum (Al), titanium (Ti), and indium tin oxide (ITO). However, the embodiments of the present specification are not limited thereto.

The micro-LED ED may be disposed in each of the plurality of subpixels. The plurality of micro-LEDs ED may be any one of a light-emitting diode (LED) or a micro-light-emitting diode (micro-LED). However, the embodiments of the present specification are not limited thereto. The plurality of micro-LEDs ED may be disposed on the bank BNK and the first electrode CE1. The plurality of micro-LEDs ED may be disposed on the first electrode CE1 and electrically connected to the first electrode CE1. Therefore, the micro-LED ED may emit light by receiving the anode voltage from the pixel drive circuit PD through the signal line TL and the first electrode CE1.

The plurality of micro-LEDs ED may include first micro-LEDs 130, second micro-LEDs 140, and third micro-LEDs 150. The first micro-LED 130 may be disposed in the first subpixel SP1. The second micro-LED 140 may be disposed in the second subpixel SP2. The third micro-LED 150 may be disposed in the third subpixel SP3. For example, any one of the first micro-LED 130, the second micro-LED 140, and the third micro-LED 150 may be a red micro-LED, another micro-LED may be a green micro-LED, the other micro-LED may be a blue micro-LED. However, the embodiments of the present specification are not limited thereto. Therefore, light beams with various colors including the white color may be implemented by combining red light, green light, and blue light emitted from the plurality of micro-LEDs ED. The types of micro-LEDs ED are illustrative. However, the embodiments of the present specification are not limited thereto.

The first micro-LEDs 130 may include a first-first micro-LED 130a disposed in the first-first subpixel SP1a, and a first-second micro-LED 130b disposed in the first-second subpixel SP1b. The second micro-LEDs 140 may include a second-first micro-LED 140a disposed in the second-first subpixel SP2a, and a second-second micro-LED 140b disposed in the second-second subpixel SP2b. The third micro-LEDs 150 may include a third-first micro-LED 150a disposed in the third-first subpixel SP3a, and a third-second micro-LED 150b disposed in the third-second subpixel SP3b.

With reference to FIGS. 5, 6, and 7 together, the second electrode CE2 may be disposed in each of the plurality of subpixels. The second electrode CE2 may be disposed on the micro-LED ED. The second electrode CE2 may be electrically connected to the pixel drive circuit PD through a plurality of contact electrodes to be described below.

For example, the second electrode CE2 may be electrically connected to a cathode electrode 135 of the micro-LED ED and transmit a cathode voltage from the pixel drive circuit PD to the micro-LED ED. The same cathode voltage may be applied to the second electrodes CE2 of the plurality of subpixels. For example, the same voltage may be applied to the second electrode CE2 and the cathode electrode 135 of the micro-LED ED in each of the plurality of subpixels. Therefore, the second electrode CE2 may be a common electrode. However, the embodiments of the present specification are not limited thereto.

At least some of the plurality of subpixels may share the second electrode CE2. At least some of the second electrodes CE2 of the plurality of subpixels may be electrically connected to one another. Because the same voltage is applied to the second electrodes CE2, at least some of the subpixels may use and share the second electrode CE2. For example, the second electrodes CE2 of the pixels PX of at least some of the plurality of pixels PX disposed in the same row may be connected to each other. For example, one second electrode CE2 may be disposed in each of the plurality of pixels PX. One second electrode CE2 may be disposed for each of n subpixels.

For example, some of the second electrodes CE2 of the plurality of subpixels may be disposed to be spaced apart or separated from one another. For example, the second electrodes CE2 connected to the pixels PX disposed in an n-th row and the second electrodes CE2 connected to the pixels PX disposed in an (n+1)-th row may be disposed to be spaced apart or separated from one another. For example, the plurality of second electrodes CE2 may be disposed to be spaced apart from one another with the plurality of communication lines NL interposed therebetween and extending in the row direction. Therefore, the number of subpixels may be larger than the number of second electrodes CE2. In another example, all the second electrodes CE2 in the plurality of subpixels may be connected to one another, and only one second electrode CE2 may be disposed on the substrate 110. However, the embodiments of the present specification are not limited thereto.

The plurality of second electrodes CE2 may be made of a transparent electrically conductive material. However, the embodiments of the present specification are not limited thereto. The plurality of second electrodes CE2 may be made of a transparent electrically conductive material, and the light emitted from the micro-LED ED may be directed toward an upper side of the second electrode CE2. For example, the second electrode CE2 may be made of a transparent electrically conductive material such as indium tin oxide (ITO), indium zinc oxide (IZO), or indium gallium zinc oxide (IGZO). However, the embodiments of the present specification are not limited thereto.

Although not illustrated in FIGS. 5 to 7, the plurality of contact electrodes may be disposed on the substrate 110. For example, the plurality of contact electrodes may be disposed to be spaced apart from the plurality of banks BNK and the plurality of signal lines TL. The plurality of second electrodes CE2 may each overlap at least one contact electrode. For example, one second electrode CE2 may overlap the plurality of contact electrodes.

For example, the plurality of contact electrodes may be electrically connected to the plurality of second electrodes CE2. The plurality of contact electrodes may be disposed between the substrate 110 and the plurality of second electrodes CE2 and transmit the cathode voltage from the pixel drive circuit PD to the second electrode CE2.

For example, in case that micro-LEDs are used as the micro-LEDs ED, the display apparatus 1000 may be manufactured by forming the plurality of micro-LEDs on a wafer and transferring the micro-LEDs to the substrate 110 of the display apparatus 1000. Various types of defects may occur during the process of transferring the plurality of micro-LEDs ED having fine sizes to the substrate 110. For example, a non-transfer defect, which is caused when the micro-LEDs ED are not transferred, may occur in some of the subpixels, and a defect, in which the micro-LEDs ED are transferred while deviating from exact positions, may occur because of alignment errors in some of the subpixels. In addition, the transferred micro-LED ED may be defective even though the transfer process is normally performed. Therefore, the plurality of micro-LEDs ED, which emit light beams with the same color, may be transferred to one subpixel in consideration of defects occurring during the process of transferring the plurality of micro-LEDs ED. A lighting inspection may be performed on the plurality of micro-LEDs ED, and only one micro-LED ED, which is finally determined as being normal, may be used.

For example, both the first-first micro-LED 130a and the first-second micro-LED 130b are transferred to one pixel PX, and whether the first-first micro-LED 130a and the first-second micro-LED 130b are defective may be inspected. If both the first-first micro-LED 130a and the first-second micro-LED 130b are determined as being normal, the first-first micro-LED 130a may be used, and the first-second micro-LED 130b may not be used. In another example, in case that the first-second micro-LED 130b between the first-first micro-LED 130a and the first-second micro-LED 130b is determined as being normal, the first-first micro-LED 130a may not be used, and the first-second micro-LED 130b may be used. Therefore, one micro-LED ED may be finally used even though the plurality of micro-LEDs ED, which emit light beams with the same color, are transferred to one pixel PX.

Therefore, any one of the pair of micro-LEDs ED may be a main (main or primary) micro-LED ED, and the other of the micro-LEDs ED may be a redundancy micro-LED ED. The redundancy micro-LED ED may be an extra micro-LED ED transferred to prepare for a defect of the main micro-LED ED. When the main micro-LED ED is defective, the redundancy micro-LED ED may be used instead of the main micro-LED ED. Therefore, both the main micro-LED ED and the redundancy micro-LED ED are transferred to one pixel PX, which may minimize a deterioration in display quality caused by defects of the main micro-LED ED and the redundancy micro-LED ED.

For example, the first-first micro-LED 130a, the second-first micro-LED 140a, and the third-first micro-LED 150a transferred to one pixel PX may be used as the main micro-LEDs ED, and the first-second micro-LED 130b, the second-second micro-LED 140b, and the third-second micro-LED 150b may be used as the redundancy micro-LEDs ED.

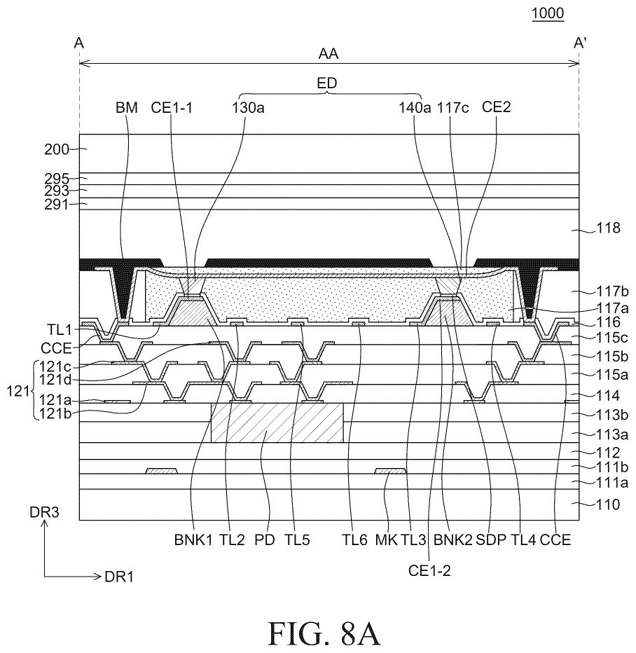

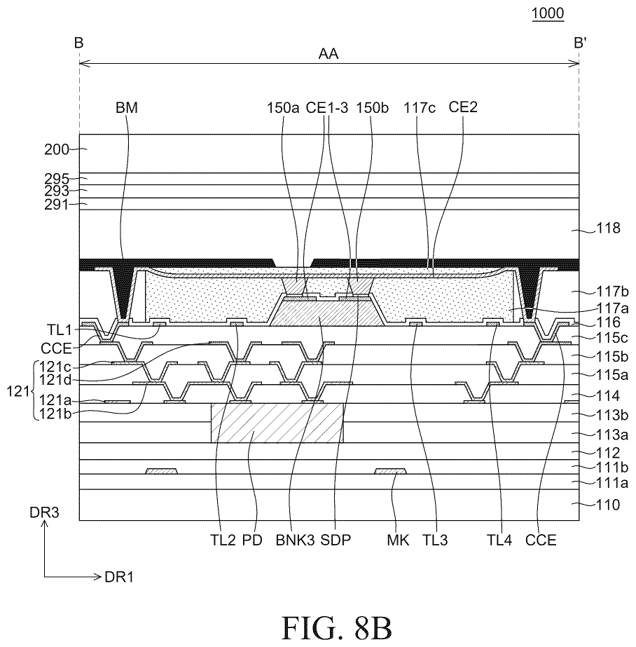

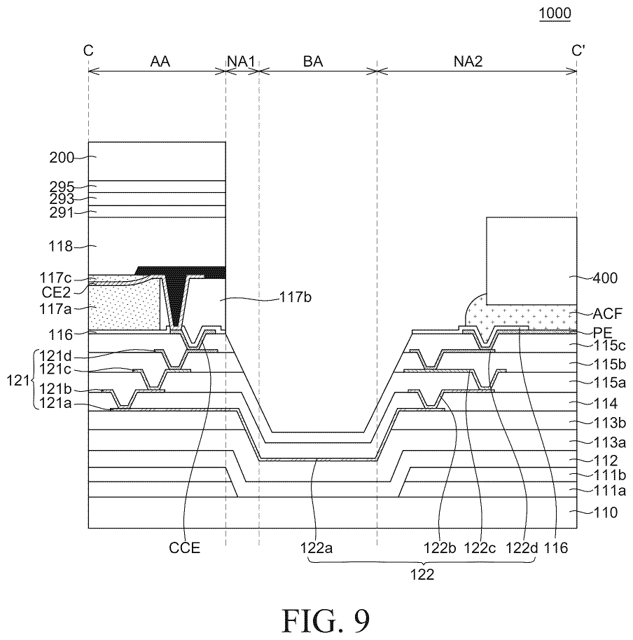

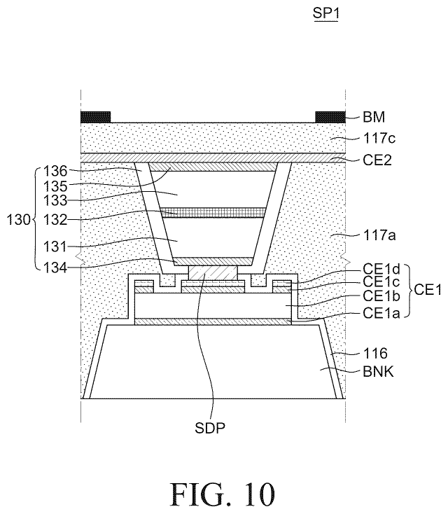

FIG. 8A is a cross-sectional view taken along line A-A′ in FIG. 5 according to an embodiment of the present specification. FIG. 8B is a cross-sectional view taken along line B-B′ in FIG. 5 according to an embodiment of the present specification. FIG. 9 is a cross-sectional view taken along line C-C′ in FIG. 3 according to an embodiment of the present specification. For example, FIGS. 8A and 8B are cross-sectional views of the display area AA according to the embodiment of the present specification. FIG. 9 is a cross-sectional view illustrating the display area AA, the first non-display area NA1, the bending area BA, and the second non-display area NA2 according to the embodiment of the present specification. Meanwhile, for convenience of illustration, FIG. 3 illustrates that the cutting line C-C′, the drive line VL, and the link line LL do not overlap one another. However, the cutting line C-C′ in FIG. 3 indicates the same position as the adjacent drive line VL and the adjacent link line LL. FIG. 10 is an enlarged cross-sectional view of the first subpixel SP1 according to the embodiment of the present specification.

With reference to FIGS. 8A and 8B, a first buffer layer 111a and a second buffer layer 111b may be disposed in the remaining area of the substrate 110, except for the bending area BA.

The first buffer layer 111a and the second buffer layer 111b may be disposed in the display area AA, the first non-display area NA1, and the second non-display area NA2. The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may each be configured as a single layer or multilayer made of silicon oxide (SiOx) or silicon nitride (SiNx). However, the embodiments of the present specification are not limited thereto.

For example, the first buffer layer 111a and the second buffer layer 111b disposed in the bending area BA may be partially removed. A top surface of the substrate 110 positioned in the bending area BA may be exposed from the first buffer layer 111a and the second buffer layer 111b. The first buffer layer 111a and the second buffer layer 111b, which are made of an inorganic insulating material, are removed from the bending area BA, which may minimize the occurrence of a crack in the first buffer layer 111a and the second buffer layer 111b that may be caused when the bending area BA is bent.

A plurality of alignment keys MK may be disposed between the first buffer layer 111a and the second buffer layer 111b. The plurality of alignment keys MK may be configured to identify a position of the pixel drive circuit PD during the process of manufacturing the display apparatus 1000. For example, the plurality of alignment keys MK may be configured to align the position of the pixel drive circuit PD transferred onto a bonding layer 112. In another example, the plurality of alignment keys MK may be excluded.

The bonding layer 112 may be disposed on the second buffer layer 111b. The bonding layer 112 may be disposed in the display area AA, the first non-display area NA1, the bending area BA, and the second non-display area NA2. In another example, at least a part of the bonding layer 112 may be removed from the non-display area NA including the bending area BA. For example, the bonding layer 112 may be made of any one of polymer (adhesive polymer), epoxy resin, UV-curable resin, polyimide, acrylate, urethane, and polydimethylsiloxane (PDMS). However, the embodiments of the present specification are not limited thereto.

The pixel drive circuit PD may be disposed on the bonding layer 112 in the display area AA. In case that the pixel drive circuit PD is implemented as an operation driver, the operation driver may be mounted on the bonding layer 112 by the transfer process. However, the embodiments of the present specification are not limited thereto.

A first protective layer 113a and a second protective layer 113b may be disposed on the bonding layer 112 and the pixel drive circuit PD. The first protective layer 113a and the second protective layer 113b may be disposed to surround a side surface of the pixel drive circuit PD. However, the embodiments of the present specification are not limited thereto. For example, the second protective layer 113b may be disposed to cover at least a part of a top surface of the pixel drive circuit PD. For example, at least one of the first protective layer 113a and the second protective layer 113b disposed on the bending area BA may be excluded. For example, the first protective layer 113a may be entirely disposed in the display area AA and the non-display area NA, and the second protective layer 113b may be partially disposed in the display area AA, the first non-display area NA1, and the second non-display area NA2. For example, a part of the second protective layer 113b disposed in the bending area BA may be removed. However, the embodiments of the present specification are not limited thereto.

The first protective layer 113a and the second protective layer 113b may each be made of an organic insulating material. However, the embodiments of the present specification are not limited thereto. For example, the first protective layer 113a and the second protective layer 113b may each be made of photoresist, polyimide (PI), or a photo acrylic material. However, the embodiments of the present specification are not limited thereto. For example, the first protective layer 113a and the second protective layer 113b may each be an overcoating layer or an insulation layer. However, the embodiments of the present specification are not limited thereto.

According to the present specification, a plurality of first connection lines 121 may be disposed on the second protective layer 113b in the display area AA. The plurality of first connection lines 121 may be lines configured to electrically connect the pixel drive circuit PD to other constituent elements. For example, the pixel drive circuit PD may be electrically connected to the plurality of signal lines TL, a plurality of contact electrodes CCE, and the like through the plurality of first connection lines 121. For example, the plurality of first connection lines 121 may include first-first connection lines 121a, first-second connection lines 121b, first-third connection lines 121c, and first-fourth connection lines 121d. However, the embodiments of the present specification are not limited thereto. The plurality of first connection lines 121 may be lines referred to as signal lines disposed on the same layer, and the plurality of first connection lines 121 may include signal lines to which different signals are applied.

For example, the plurality of first-first connection lines 121a may be disposed on the second protective layer 113b. The plurality of first-first connection lines 121a may be electrically connected to the pixel drive circuit PD. The plurality of first-first connection lines 121a may transmit a voltage, which is outputted from the pixel drive circuit PD, to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover or surround a side surface of the second protective layer 113b and a top surface of the first protective layer 113a. The third protective layer 114 may be made of an organic insulating material. For example, the third protective layer 114 may be made of photoresist, polyimide (PI), or a photo acrylic material. However, the embodiments of the present specification are not limited thereto. For example, the first protective layer 113a, the second protective layer 113b, and the third protective layer 114 may be made of the same or substantially same material. However, the embodiments of the present specification are not limited thereto. The embodiments of the present specification are not limited thereto.

The plurality of first-second connection lines 121b may be disposed on the third protective layer 114. The plurality of first-second connection lines 121b may be connected indirectly or directly to the pixel drive circuit PD. For example, a part of the first-second connection line 121b may be connected directly to the pixel drive circuit PD through a contact hole of the third protective layer 114. Another part of the first-second connection line 121b may be electrically connected to the first-first connection line 121a through the contact hole of the third protective layer 114.

However, the embodiments of the present specification are not limited thereto. The voltage outputted from the pixel drive circuit PD may be transmitted to the first electrode CE1 or the second electrode CE2 through a connection line different from the plurality of first-second connection lines 121b.

A first insulation layer 115a may be disposed on the plurality of first-second connection lines 121b. The first insulation layer 115a may be entirely disposed in the display area AA and the non-display area NA. However, the embodiments of the present specification are not limited thereto. The first insulation layer 115a may be made of an organic insulating material. However, the embodiments of the present specification are not limited thereto. For example, the first insulation layer 115a may be made of photoresist, polyimide (PI), or a photo acrylic material. However, the embodiments of the present specification are not limited thereto.

The plurality of first-third connection lines 121c may be disposed on the first insulation layer 115a. The plurality of first-third connection lines 121c may be electrically connected to the plurality of first-second connection lines 121b. For example, the first-third connection line 121c may be electrically connected to the first-second connection line 121b through a contact hole of the first insulation layer 115a.

A second insulation layer 115b may be disposed on the plurality of first-third connection lines 121c. The second insulation layer 115b may be disposed in the remaining area, except for the bending area BA. However, the embodiments of the present specification are not limited thereto. The second insulation layer 115b may be disposed in the display area AA, the first non-display area NA1, and the second non-display area NA2. However, the embodiments of the present specification are not limited thereto. For example, a part of the second insulation layer 115b disposed in the bending area BA may be removed. The second insulation layer 115b may be made of an organic insulating material. However, the embodiments of the present specification are not limited thereto. For example, the second insulation layer 115b may be made of photoresist, polyimide (PI), or a photo acrylic material. However, the embodiments of the present specification are not limited thereto.

The plurality of first-fourth connection lines 121d may be disposed on the second insulation layer 115b. The plurality of first-fourth connection lines 121d may be electrically connected to the plurality of first-third connection lines 121c. For example, the first-fourth connection line 121d may be electrically connected to the first-third connection line 121c through the contact hole of the second insulation layer 115b.

The plurality of signal lines TL may be disposed on the third insulation layer 115c in the display area AA. The plurality of signal lines TL may be disposed in areas between the plurality of banks BNK. For example, the plurality of signal lines TL may be disposed adjacent to any one of the plurality of banks BNK.

According to the present specification, a plurality of second connection lines 122 may be disposed on the second protective layer 113b in the non-display area NA. The plurality of second connection lines 122 may be lines configured to transmit the signals, which are transmitted to the pad part PAD from the flexible circuit board (or flexible film) 400 and the printed circuit board 500 (see FIG. 1), to the pixel drive circuit PD in the display area AA. For example, the plurality of second connection lines 122 may be electrically connected to the plurality of pad electrodes PE and receive the signals from the flexible circuit board (or flexible film) 400 and the printed circuit board 500. For example, the second connection lines 122 may transmit signals, which are transmitted to the pad part PAD through the plurality of first connection lines 121 disposed in the display area AA, to the pixel drive circuit PD.

For example, the plurality of second connection lines 122 may extend from the pad part PAD toward the display area AA and transmit signals to the lines in the display area AA. In this case, the plurality of second connection lines 122 may serve as the link lines LL. The plurality of second connection lines 122 may include second-first connection lines 122a, second-second connection lines 122b, second-third connection lines 122c, and second-fourth connection lines 122d.

The plurality of second-first connection lines 122a may be disposed on the second protective layer 113b. The plurality of second-first connection lines 122a may extend from the second non-display area NA2 to the bending area BA and the first non-display area NA1. The plurality of second-first connection lines 122a may transmit the signals, which are transmitted to the pad part PAD from the flexible circuit board (or flexible film) 400 and the printed circuit board 500, to the pixel drive circuit PD in the display area AA.

The plurality of second-second connection lines 122b may be disposed on the third protective layer 114. The plurality of second-second connection lines 122b may be disposed in the second non-display area NA2. The second-second connection line 122b may be electrically connected to the second-first connection line 122a through the contact hole of the third protective layer 114. Therefore, the signals may be transmitted from the flexible circuit board (or flexible film) 400 and the printed circuit board 500 to the second-first connection line 122a through the second-second connection line 122b.

The second-third connection line 122c may be disposed on the first insulation layer 115a. The second-third connection line 122c may be disposed in the second non-display area NA2. The second-third connection line 122c may be electrically connected to the second-second connection line 122b through the contact hole of the first insulation layer 115a. Therefore, the signals may be transmitted from the flexible circuit board (or flexible film) 400 and the printed circuit board 500 to the second-first connection line 122a through the second-third connection line 122c and the second-second connection line 122b.

The second-fourth connection line 122d may be disposed on the second insulation layer 115b. The second-fourth connection line 122d may be disposed in the second non-display area NA2. The second-fourth connection line 122d may be electrically connected to the second-third connection line 122c through the contact hole of the second insulation layer 115b. Therefore, the signals may be transmitted from the flexible circuit board (or flexible film) 400 and the printed circuit board 500 to the second-first connection line 122a through the second-fourth connection line 122d, the second-third connection line 122c, and the second-second connection line 122b.

The plurality of first connection lines 121 and the plurality of second connection lines 122 may be made of any one of electrically conductive materials with excellent flexibility or various electrically conductive materials used for the display area AA. For example, the second connection line 122 partially disposed in the bending area BA may be made of an electrically conductive material, such as gold (Au), silver (Ag), or aluminum (Al), that is excellent in flexibility. However, the embodiments of the present specification are not limited thereto. In another example, the plurality of first connection lines 121 and the plurality of second connection lines 122 may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present specification are not limited thereto.

A third insulation layer 115c may be disposed on the plurality of first connection lines 121 and the plurality of second connection lines 122. The third insulation layer 115c may be disposed in the remaining area, except for the bending area BA. However, the embodiments of the present specification are not limited thereto. The third insulation layer 115c may be disposed in the display area AA, the first non-display area NA1, and the second non-display area NA2. A part of the third insulation layer 115c disposed in the bending area BA may be removed. The third insulation layer 115c may be made of an organic insulating material. However, the embodiments of the present specification are not limited thereto. For example, the third insulation layer 115c may be made of photoresist, polyimide (PI), or a photo acrylic material. However, the embodiments of the present specification are not limited thereto. The plurality of banks BNK may be disposed on the third insulation layer 115c in the display area AA. The plurality of banks BNK may be disposed to overlap the plurality of subpixels. One or more micro-LEDs ED, which emit light beams with the same color, may be disposed on upper portions of the plurality of banks BNK.

With reference to FIG. 8A, a short axis of the first bank BNK1 and a short axis of the second bank BNK2 may be disposed in the first direction DR1.

With reference to FIG. 8B, a long axis of the third bank BNK3 may be disposed in the first direction DR1, and the third-first micro-LED 150a and the third-second micro-LED 150b, which emit light beams with the same color, may be disposed in the first direction DR1.

The plurality of contact electrodes CCE may be disposed on the third insulation layer 115c in the display area AA. The plurality of contact electrodes CCE may supply the cathode voltage from the pixel drive circuit PD to the second electrode CE2.

The first electrode CE1 may be disposed on the bank BNK. For example, the first electrode CE1 may be disposed to extend from the adjacent signal line TL to the upper side of the bank BNK. The first electrode CE1 may be disposed on the top surface of the bank BNK and the side surface of the bank BNK. For example, the first electrode CE1 may be disposed to extend from the signal line TL on the top surface of the third insulation layer 115c to the side surface of the bank BNK and the top surface of the bank BNK.

With reference to FIG. 8A, the first-first electrode CE1-1 may be disposed on the first bank BNK1. The first-first electrode CE1-1 may extend in the first direction DR1 on the first bank BNK1 and connect the first-first micro-LED 130a and the first signal line TL1. In addition, the first-second electrode CE1-2 may be disposed on the second bank BNK2. The first-second electrode CE1-2 may extend in the first direction DR1 on the second bank BNK2 and connect the second-first micro-LED 140a and the third signal line TL3.

With reference to FIG. 8B, the first-third electrode CE1-3 may be disposed on the third bank BNK3. With reference to FIG. 6 together, the first-third electrode CE1-3 may extend in the second direction DR2 on the third bank BNK3 and be connected to the fifth signal line TL5 and the sixth signal line TL6.

With reference to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d. However, the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be made of titanium (Ti), molybdenum (Mo), aluminum (Al), titanium (Ti), or indium tin oxide (ITO). However, the embodiments of the present specification are not limited thereto.

According to the present specification, among the plurality of conductive layers constituting the first electrode CE1, some conductive layers with high reflection efficiency may include alignment keys for aligning the micro-LEDs ED, and/or reflective plates. For example, among the plurality of conductive layers of the first electrode CE1, the second conductive layer CE1b may include a reflective material. For example, the second conductive layer CE1b may include aluminum (Al). However, the embodiments of the present specification are not limited thereto. Therefore, the second conductive layer CE1b may be configured as a reflective plate. In addition, with the high reflection efficiency of the second conductive layer CE1b, the second conductive layer CE1b may be easily identified during the manufacturing process. Therefore, the position or transfer position of the micro-LED ED may be aligned with respect to the second conductive layer CE1b.

For example, in order to configure the second conductive layer CE1b as a reflective plate, the third conductive layer CE1c and the fourth conductive layer CE1d, which cover the second conductive layer CE1b, may be partially removed or etched. For example, the third conductive layer CE1c and the fourth conductive layer CE1d disposed on the bank BNK may be partially removed or etched, such that a top surface of the second conductive layer CE1b may be exposed. For example, central portions and rim portions (or edge portions) of the third conductive layer CE1c and the fourth conductive layer CE1d where solder patterns SDP are disposed may be maintained, and the remaining portions excluding the above-mentioned portions may be removed. For example, the rim portion (or edge portion) of the third conductive layer CE1c made of titanium (Ti) and the rim portion (or edge portion) of the fourth conductive layer CE1d made of indium tin oxide (ITO) may not be etched. Therefore, it is possible to inhibit the other conductive layers of the first electrode CE1 from being corroded by a tetramethyl ammonium hydroxide (TMAH) solution used for a mask process for the first electrode CE1.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer made of indium tin oxide (ITO) or indium zinc oxide (IZO) having high bondability to the solder pattern SDP and having corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned by a photolithography process and an etching process. However, the embodiments of the present specification are not limited thereto.

According to the present specification, the signal line TL, the contact electrode CCE, and the pad electrode PE disposed on the same layer as the first electrode CE1 may each be configured as a multilayer made of an electrically conductive material. However, the embodiments of the present specification are not limited thereto. For example, the signal line TL, the contact electrode CCE, and the pad electrode PE may each be configured as a multilayer made of indium tin oxide (ITO), titanium (Ti), aluminum (Al), and titanium (Ti). However, the embodiments of the present specification are not limited thereto.

According to the present specification, the solder pattern SDP may be disposed on the first electrode CE1 in each of the plurality of subpixels. The solder pattern SDP may electrically connect the first electrode CE1 and the micro-LED ED by bonding the micro-LED ED to the first electrode CE1. For example, the first electrode CE1 and the anode electrode 134 of the micro-LED ED may be electrically connected by eutectic bonding using the solder pattern SDP. However, the embodiments of the present specification are not limited thereto. For example, in case that the solder pattern SDP is made of indium (In) and the anode electrode 134 of the micro-LED ED is made of gold (Au), the solder pattern SDP and the anode electrode 134 may be joined by applying heat and pressure during the process of transferring the micro-LED ED. The micro-LED ED may be joined to the solder pattern SDP and the first electrode CE1 by eutectic bonding without a separate bonding material. For example, the solder pattern SDP may be made of indium (In), tin (Sn), or an alloy thereof. However, the embodiments of the present specification are not limited thereto. For example, the solder pattern SDP may be a bonding pad or a joining pad. However, the embodiments of the present specification are not limited thereto.

According to the present specification, a passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A part of the passivation layer 116 disposed in the bending area BA may be removed. A part of the passivation layer 116, which covers the plurality of pad electrodes PE in the second non-display area NA2, may be removed. The passivation layer 116 is disposed to cover the remaining area excluding the areas in which the bending area BA, the plurality of pad electrodes PE, and the solder pattern SDP are disposed, and as a result, it is possible to the permeation of moisture or impurities introduced into the micro-LED ED. For example, the passivation layer 116 may be configured as a single layer or multilayer made of silicon oxide (SiOx) or silicon nitride (SiNx). However, the embodiments of the present specification are not limited thereto. For example, the passivation layer 116 may be a protective layer, an insulation layer, or the like. However, the embodiments of the present specification are not limited thereto. For example, the passivation layer 116 may include a hole through which the solder pattern SDP is exposed.

In each of the plurality of subpixels, the micro-LED ED may be disposed on the solder pattern SDP. The first micro-LED 130 may be disposed in the first subpixel SP1. The second micro-LED 140 may be disposed in the second subpixel SP2. The third micro-LED 150 may be disposed in the third subpixel SP3.

With reference to FIG. 8A, in one pixel PX, the first-first micro-LED 130a and the second-first micro-LED 140a, which emit light beams with different colors, may be sequentially disposed in the first direction DR1.

In addition, with reference to FIG. 8B, the third-first micro-LED 150a and the third-second micro-LED 150b, which emit light beams with the same color, may be disposed in the first direction DR1.

Meanwhile, between the third-first micro-LED 150a and the third-second micro-LED 150b, the third-first micro-LED 150a may be a main micro-LED, and the third-second micro-LED 150b may be a redundancy micro-LED. The redundancy micro-LED may be an extra micro-LED transferred to prepare for a defect of the main micro-LED. In this case, the third-second micro-LED 150b, which is the redundancy micro-LED, may be covered by a black matrix BM. As described above, the black matrix BM is disposed on the micro-LED that is not used, such that it is possible to inhibit a non-light-emitting micro-LED, which is not used, from being visually recognized from the outside. However, the embodiments of the present specification are not limited thereto.

The micro-LED ED may be formed on a silicon wafer by a method such as metal-organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering. However, the embodiments of the present specification are not limited thereto.

With reference to FIG. 10, the first micro-LED 130 may include the anode electrode 134, a first semiconductor layer 131, an active layer 132, a second semiconductor layer 133, the cathode electrode 135, and an encapsulation film 136. However, the embodiments of the present specification are not limited thereto. For example, the first micro-LED 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a III-V group or II-VI group compound semiconductor and doped with impurities (or dopant). For example, one of the first semiconductor layer 131 and the second semiconductor layer 133 may be a semiconductor layer doped with n-type impurities, and the other of the first semiconductor layer 131 and the second semiconductor layer 133 may be a semiconductor layer doped with p-type impurities. However, the embodiments of the present specification are not limited thereto. For example, one of or both the first semiconductor layer 131 and the second semiconductor layer 133 may be layers made by doping a material such as gallium nitride (GaN), gallium phosphide (GaP), gallium arsenide phosphide (GaAsP), aluminum gallium indium phosphide (AlGalnP), indium aluminum phosphide (InAIP), aluminum gallium nitride (AlGaN), aluminum indium nitride (AlInN), aluminum indium gallium nitride (AlInGaN), aluminum gallium arsenide (AlGaAs), or gallium arsenide (GaAs) with n-type or p-type impurities. However, the embodiments of the present specification are not limited thereto. For example, the n-type impurity may be silicon (Si), germanium (Ge), selenium (Se), carbon (C), tellurium (Te), tin (Sn), or the like. However, the embodiments of the present specification are not limited thereto. For example, the p-type impurity may be magnesium (Mg), zinc (Zn), calcium (Ca), strontium (Sr), barium (BA), beryllium (Be), or the like. However, the embodiments of the present specification are not limited thereto.

For example, the first semiconductor layer 131 and the second semiconductor layer 133 may be respectively a nitride semiconductor containing n-type impurities and a nitride semiconductor containing p-type impurities. However, the embodiments of the present specification are not limited thereto. For example, the first semiconductor layer 131 may be a nitride semiconductor containing p-type impurities, and the second semiconductor layer 133 may be a nitride semiconductor containing n-type impurities. However, the embodiments of the present specification are not limited thereto.

The active layer 132 may be disposed between the first semiconductor layer 131 and the second semiconductor layer 133. The active layer 132 may emit light by receiving positive holes and electrons from the first semiconductor layer 131 and the second semiconductor layer 133. For example, the active layer 132 may have any one of a single well structure, a multi-well structure, a single quantum well structure, a multi-quantum well (MQW) structure, a quantum dot structure, and a quantum line structure. However, the embodiments of the present specification are not limited thereto. For example, the active layer 132 may be made of indium gallium nitride (InGaN), gallium nitride (GaN), or the like. However, the embodiments of the present specification are not limited thereto.

In another example, the active layer 132 may include a multi-quantum well (MQW) structure having a well layer, and a barrier layer having a higher band gap than the well layer. For example, the active layer 132 may configure an InGaN layer as the well layer and configure an AlGaN layer as the barrier layer. However, the embodiments of the present specification are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage outputted from the pixel drive circuit PD may be applied to the first semiconductor layer 131 through the signal line TL, the first electrode CE1, and the anode electrode 134. For example, the anode electrode 134 may be made of an electrically conductive material that may be bonded to the solder pattern SDP by eutectic bonding. However, the embodiments of the present specification are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, the embodiments of the present specification are not limited thereto.

The cathode electrode 135 may be disposed on the second semiconductor layer 133. For example, the cathode electrode 135 may electrically connect the second semiconductor layer 133 and the second electrode CE2. The cathode voltage outputted from the pixel drive circuit PD may be applied to the second semiconductor layer 133 through the contact electrode CCE, the second electrode CE2, and the cathode electrode 135. The cathode electrode 135 may be made of a transparent electrically conductive material so that the light emitted from the micro-LED ED may propagate to the upper side of the micro-LED ED. However, the embodiments of the present specification are not limited thereto. For example, the cathode electrode 135 may be made of a material such as indium tin oxide (ITO), indium zinc oxide (IZO), or indium gallium zinc oxide (IGZO). However, the embodiments of the present specification are not limited thereto.

The encapsulation film 136 may be at least partially disposed on the first semiconductor layer 131, the active layer 132, the second semiconductor layer 133, the anode electrode 134, and the cathode electrode 135. For example, the encapsulation film 136 may at least partially surround the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and at least a part of the cathode electrode 135, e.g., an edge portion (or edge portion or one side) of the anode electrode 134 and an edge portion (or edge portion or one side) of the cathode electrode 135. At least a part of the anode electrode 134 may be exposed from the encapsulation film 136, such that the anode electrode 134 and the solder pattern SDP may be connected. For example, at least a part of the cathode electrode 135 may be exposed from the encapsulation film 136, such that the cathode electrode 135 and the second electrode CE2 may be connected. For example, the encapsulation film 136 may be made of an insulating material such as silicon nitride (SiNx) or silicon oxide (SiOx). However, the embodiments of the present specification are not limited thereto.

In another example, the encapsulation film 136 may have a structure in which a reflective material is dispersed in a resin layer. However, the embodiments of the present specification are not limited thereto. For example, the encapsulation film 136 may be manufactured as a reflector having various structures. However, the embodiments of the present specification are not limited thereto. The light emitted from the active layer 132 is reflected upward by the encapsulation film 136, which may improve the light extraction efficiency. For example, the encapsulation film 136 may be a reflective layer. However, the embodiments of the present specification are not limited thereto.

According to the present specification, the micro-LED ED has been described as having a vertical structure. However, the embodiments of the present specification are not limited thereto. For example, the micro-LED ED may have a lateral structure or a flip chip structure.

The first micro-LED 130 has been described with reference to FIG. 10. The second micro-LED 140 and the third micro-LED 150 may have substantially the same structure as the first micro-LED 130. For example, the first semiconductor layer 131, the active layer 132, the second semiconductor layer 133, the anode electrode 134, the cathode electrode 135, and the encapsulation film 136 of the first micro-LED 130 may be substantially identical to those of the second micro-LED 140 and the third micro-LED 150.

According to the present specification, first optical layers 117a may be disposed to surround the plurality of micro-LEDs ED in the display area AA. For example, the first optical layers 117a may be disposed to cover the plurality of micro-LEDs ED and the bank BNK in the areas of the plurality of subpixels. For example, the first optical layer 117a may cover the bank BNK, a part of the passivation layer 116, and the portions between the plurality of micro-LEDs ED. The first optical layers 117a may be disposed between the plurality of micro-LEDs ED included in one pixel PX and between the plurality of banks BNK or cover the plurality of micro-LEDs ED and the plurality of banks BNK. For example, the first optical layer 117a may be disposed between the passivation layer 116 and the second electrode CE2 and surround a lateral portion of the micro-LED ED and a lateral portion of the bank BNK. However, the embodiments of the present specification are not limited thereto. For example, the first optical layer 117a may be a diffusion layer, a sidewall diffusion layer, or the like. However, the embodiments of the present specification are not limited thereto.

The first optical layer 117a may include an organic insulating material in which fine particles are dispersed. However, the embodiments of the present specification are not limited thereto. For example, the first optical layer 117a may be made of siloxane in which fine metal particles such as titanium dioxide (TiO₂) particles are dispersed. However, the embodiments of the present specification are not limited thereto. The light emitted from the plurality of micro-LEDs ED may be scattered by the fine particles dispersed in the first optical layer 117a, and the light may be discharged to the outside of the display apparatus 1000. Therefore, the first optical layer 117a may improve the efficiency in extracting light emitted from the plurality of micro-LEDs ED.

For example, the first optical layer 117a may be respectively disposed in the plurality of pixels PX or disposed together with some of the pixels PX disposed in the same row. However, the embodiments of the present specification are not limited thereto. For example, the first optical layer 117a may be disposed in each of the plurality of pixels PX, or the plurality of pixels PX may share one first optical layer 117a. In another example, the plurality of subpixels may each separately include the first optical layer 117a. However, the embodiments of the present specification are not limited thereto.

According to the present specification, a second optical layer 117b may be disposed on the passivation layer 116 in the display area AA. For example, the second optical layer 117b may be disposed to surround the first optical layer 117a. For example, the second optical layer 117b may adjoin a side surface of the first optical layer 117a. For example, the second optical layer 117b may be disposed in an area between the plurality of pixels PX. However, the embodiments of the present specification are not limited thereto. For example, the second optical layer 117b may be a diffusion layer, a diffusion layer window, a window diffusion layer, or the like. However, the embodiments of the present specification are not limited thereto.

The second optical layer 117b may be made of an organic insulating material. However, the embodiments of the present specification are not limited thereto. The second optical layer 117b may be made of the same or substantially same material as the first optical layer 117a. However, the embodiments of the present specification are not limited thereto. For example, the first optical layer 117a may include fine particles, and the second optical layer 117b may include no fine particle. For example, the second optical layer 117b may be made of siloxane. However, the embodiments of the present specification are not limited thereto.

For example, a thickness of the first optical layer 117a may be smaller than a thickness of the second optical layer 117b. However, the embodiments of the present specification are not limited thereto. Therefore, when viewed in a plan view, an area, in which the first optical layer 117a is disposed, may include a concave portion recessed inward from a top surface of the second optical layer 117b.

According to the present specification, the second electrode CE2 may be disposed on the first optical layer 117a and the second optical layer 117b. For example, the second electrode CE2 may be electrically connected to the plurality of contact electrodes CCE through the contact hole of the second optical layer 117b. For example, the second electrode CE2 may be disposed on the plurality of micro-LEDs ED. For example, the second electrode CE2 may include a transparent conductive oxide made of indium tin oxide (ITO), indium zinc oxide (IZO), or the like. However, the embodiments of the present specification are not limited thereto. For example, the second electrode CE2 may be disposed to be in contact with the cathode electrode 135. For example, the second electrode CE2 may overlap the first optical layer 117a. In addition, the second electrode CE2 may extend to the outside of the first optical layer 117a.

The second electrode CE2 may continuously extend in the second direction DR2 of the substrate 110. Therefore, the second electrode CE2 may be connected in common to the plurality of pixels PX arranged in the second direction DR2 of the substrate 110. For example, the second electrode CE2 may be connected in common to the plurality of pixels PX.

According to the present specification, the second electrode CE2 may continuously extend on the first optical layer 117a, the second optical layer 117b, and the micro-LED ED. The area, in which the first optical layer 117a is disposed, may include the concave portion recessed inward from the top surface of the second optical layer 117b. Therefore, because a first portion of the second electrode CE2 disposed on the first optical layer 117a is disposed along the concave portion, the first portion of the second electrode CE2 may be disposed at a position lower than a second portion of the second electrode CE2 disposed on the second optical layer 117b.

A third optical layer 117c may be disposed on the second electrode CE2. The third optical layer 117c may be disposed to overlap the plurality of micro-LEDs ED and the first optical layer 117a. Because the third optical layer 117c is disposed above the second electrode CE2 and the plurality of micro-LEDs ED, it is possible to suppress a Mura that may occur in some of the plurality of micro-LEDs ED. For example, when the plurality of micro-LEDs ED is transferred onto the substrate 110 of the display apparatus 1000, there may occur an area in which intervals between the plurality of micro-LEDs ED are not uniform because of a process deviation or the like. In case that the intervals between the plurality of micro-LEDs ED are not uniform, light-emitting areas of the plurality of micro-LEDs ED may be disposed non-uniformly, and a user may visually recognize a Mura. Therefore, the third optical layer 117c, which is configured to uniformly diffuse light, is provided above the plurality of micro-LEDs ED, which may reduce a situation in which the light emitted from some of the micro-LEDs ED is visually recognized as a Mura. Therefore, the light emitted from the plurality of micro-LEDs ED may be uniformly diffused by the third optical layer 117c and extracted to the outside of the display apparatus 1000, which may improve the luminance uniformity of the display apparatus 1000.

The third optical layer 117c may be made of an organic insulating material in which fine particles are dispersed. However, the embodiments of the present specification are not limited thereto. For example, the third optical layer 117c may be made of siloxane in which fine metal particles such as titanium dioxide (TiO₂) particles are dispersed. However, the embodiments of the present specification are not limited thereto. For example, the third optical layer 117c may be made of the same or substantially same material as the first optical layer 117a. However, the embodiments of the present specification are not limited thereto. For example, the third optical layer 117c may be a diffusion layer or a top diffusion layer. However, the embodiments of the present specification are not limited thereto.

According to the present specification, the light emitted from the plurality of micro-LEDs ED may be scattered by the fine particles dispersed in the third optical layer 117c, and the light may be discharged to the outside of the display apparatus 1000. The third optical layer 117c may uniformly mix the light beams emitted from the plurality of micro-LEDs ED, which may further improve the luminance uniformity of the display apparatus 1000. Further, the light extraction efficiency of the display apparatus 1000 may be improved by the light scattered by the plurality of fine particles, such that the display apparatus 1000 may operate with low power consumption.

The black matrix BM may be disposed on the second electrode CE2, the first optical layer 117a, the second optical layer 117b, and the third optical layer 117c in the display area AA. For example, the contact hole of the second optical layer 117b may be filled with the black matrix BM. Because the black matrix BM is configured to cover the display area AA, it is possible to reduce a color mixture and external light reflection of the light emitted from the plurality of subpixels. For example, the black matrix BM is disposed even in the contact hole through which the second electrode CE2 and the contact electrode CCE are connected, which may suppress a leak of light between the plurality of adjacent subpixels.

For example, the black matrix BM may be made of an opaque material. However, the embodiments of the present specification are not limited thereto. For example, the black matrix BM may be made of an organic insulating material to which a black pigment or a black dye is added. However, the embodiments of the present specification are not limited thereto.

A cover layer 118 may be disposed on the black matrix BM in the display area AA. The cover layer 118 may protect components disposed below the cover layer 118. For example, the cover layer 118 may be made of an organic insulating material. However, the embodiments of the present specification are not limited thereto. For example, the cover layer 118 may be made of photoresist, polyimide (PI), or a photo acrylic material. However, the embodiments of the present specification are not limited thereto. For example, the cover layer 118 may be an overcoating layer, an insulation layer, or the like. However, the embodiments of the present specification are not limited thereto.

The polarizing layer 293 may be disposed on the cover layer 118 by means of a first bonding layer 291. The cover member 200 may be disposed on the polarizing layer 293 by means of a second bonding layer 295. For example, the first bonding layer 291 and the second bonding layer 295 may each include an optically clear adhesive (OCA), an optically clear resin (OCR), a pressure-sensitive adhesive (PSA), or the like. However, the embodiments of the present specification are not limited thereto.

According to the present specification, the plurality of pad electrodes PE may be disposed on the third insulation layer 115c in the second non-display area NA2. For example, the plurality of pad electrodes PE may be at least partially exposed from the passivation layer 116. For example, the plurality of pad electrodes PE may be electrically connected to the second-fourth connection line 122d through the contact hole of the third insulation layer 115c.

A bonding layer ACF may be disposed on the plurality of pad electrodes PE. The bonding layer ACF may be a bonding layer made by dispersing conductive balls in an insulating material. However, the embodiments of the present specification are not limited thereto. In case that heat or pressure is applied to the bonding layer ACF, the conductive balls are electrically connected in a portion to which heat or pressure is applied, such that the bonding layer ACF may have conductive properties. The bonding layer ACF may be disposed between the plurality of pad electrodes PE and the flexible circuit board (or flexible film) 400 and attach or bond the flexible circuit board (or flexible film) 400 to the plurality of pad electrodes PE. For example, the bonding layer ACF may be an anisotropic conductive film (ACF). However, the embodiments of the present specification are not limited thereto.

The flexible circuit board (or flexible film) 400 may be disposed on the bonding layer ACF. The flexible circuit board (or flexible film) 400 may be electrically connected to the plurality of pad electrodes PE through the bonding layer ACF. Therefore, the signals outputted from the flexible circuit board (or flexible film) 400 and the printed circuit board 500 may be transmitted to the pixel drive circuit PD in the display area AA through the plurality of pad electrodes PE, the second-fourth connection line 122d, the second-third connection line 122c, the second-second connection line 122b, and the second-first connection line 122a.

The plurality of banks may be disposed to be spaced apart from one another at predetermined intervals between the subpixels in order to easily identify the positions of the subpixels. For example, the plurality of banks may be spaced apart from one another in consideration of the sizes of the micro-LEDs and transfer process margins. However, the resolution of the display apparatus may deteriorate in case that the subpixels, which emit light beams with different colors, are sequentially disposed. For example, a pitch of the pixel may be determined depending on the size of the bank and the interval between the banks. For example, in case that the first subpixel, the second subpixel, and the third subpixel are sequentially disposed in the first direction in one pixel, a minimum pitch of the pixel in the first direction may correspond to a sum of a length of the first bank, a length of the second bank, lengths of the third banks, an interval between the first bank and the second bank, and an interval between the second bank and the third bank.

In the display apparatus 1000 according to the embodiment of the present specification, in one pixel PX, the first subpixels SP1 and the second subpixels SP2 are disposed in the first direction DR1 in the first column, and the third subpixels SP3 are disposed in the second column. Therefore, the minimum pitch of the pixel in the first direction DR1 may correspond to a length of the first bank BNK1, a length of the second bank BNK2, and an interval between the first bank BNK1 and the second bank BNK2 or correspond to lengths of the third banks BNK3 and an interval between the third banks BNK3. For example, in case that all the first bank BNK1, the second bank BNK2, and the third bank BNK3 have the same or substantially same size, the minimum pitch of the pixel in the first direction DR1 may correspond to the length of the first bank BNK1, the length of the second bank BNK2, and the interval between the first bank BNK1 and the second bank BNK2. Therefore, in one pixel PX, the pitch of the pixel PX in the first direction DR1 may be reduced by the length of the third bank BNK3 in the first direction DR1 and the interval between the second bank BNK2 and the third bank BNK3 in comparison with the case in which the first subpixel, the second subpixel, and the third subpixel are sequentially disposed in the first direction in one pixel. Therefore, in the display apparatus 1000 according to the embodiment of the present specification, the pitch of the pixel PX may be reduced, such that a larger number of pixels PX may be disposed when the area remains the same or substantially same, thereby implementing the high-resolution display apparatus.

Meanwhile, the pair of micro-LEDs, which emit light beams with the same color, may be disposed on each of the plurality of banks. Therefore, the plurality of banks each have a long axis in a direction in which the pair of micro-LEDs are disposed. For example, the pair of micro-LEDs may be disposed in the second direction on each of the banks. In this case, the plurality of banks may each have a short axis in the first direction, and a long axis in the second direction. Meanwhile, in case that all the micro-LEDs, which emit light beams with the same color, are disposed in the same or substantially same direction in one pixel, the resolution of the display apparatus may deteriorate. For example, in case that the pair of first micro-LEDs, the pair of second micro-LEDs, and the pair of third micro-LEDs are disposed in the second direction, the pitch of the pixel in the second direction may correspond to three times the long axis of the bank and twice the interval between the banks.

In the display apparatus 1000 according to the embodiment of the present specification, the pair of micro-LEDs ED disposed on one bank BNK are disposed in different directions. For example, the first-first micro-LED 130a and the first-second micro-LED 130b are disposed in the second direction DR2 on the first bank BNK1, the second-first micro-LED 140a and the second-second micro-LED 140b are disposed in the second direction DR2 on the second bank BNK2, and the third-first micro-LED 150a and the third-second micro-LED 150b are disposed in the first direction DR1 on the third bank BNK3. Therefore, in case that all the first bank BNK1, the second bank BNK2, and the third bank BNK3 have the same or substantially same size, the minimum pitch of the pixel in the second direction DR2 may correspond to a sum of the long axis of the bank BNK, the short axis of the bank BNK, and the distance between the banks BNK. Therefore, in the display apparatus 1000 according to the embodiment of the present specification, the pitch of the pixel PX in the second direction DR2 may be reduced in comparison with the case in which both the pair of micro-LEDs ED, which emit light beams with the same color, are arranged in the second direction DR2 in one pixel PX.

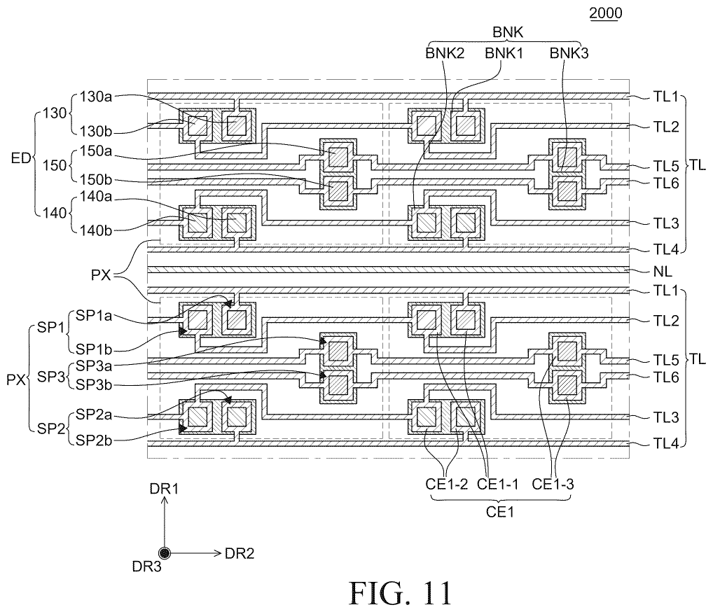

FIG. 11 is a cross-sectional view of a display apparatus according to another embodiment of the present specification. The display apparatus in FIG. 11 is substantially identical in configuration to the display apparatus 1000 in FIGS. 1 to 10, except for the plurality of signal lines TL, the plurality of first electrodes CE1, and the plurality of banks BNK. Therefore, repeated descriptions of the identical components will be omitted.

With reference to FIG. 11, the plurality of signal lines TL may be disposed in areas between the plurality of subpixels.

The plurality of signal lines TL may include the first signal line TL1, the second signal line TL2, the fifth signal line TL5, the sixth signal line TL6, the third signal line TL3, and the fourth signal line TL4 sequentially disposed in the first direction DR1.

Some of the plurality of signal lines TL may each be disposed straight in the second direction DR2. For example, the first signal line TL1 and the fourth signal line TL4 may be disposed straight in the second direction DR2.

Some of the plurality of signal lines TL may each be disposed in a curved shape extending in the first direction DR1 and the second direction DR2. For example, the second signal line TL2, the third signal line TL3, the fifth signal line TL5, and the sixth signal line TL6 may each be disposed in a shape curved in the first direction DR1 and the second direction DR2. In another example, the second signal line TL2, the third signal line TL3, the fifth signal line TL5, and the sixth signal line TL6 may each be disposed in a shape curved along an outer periphery of each of the plurality of banks BNK. For example, the second signal line TL2 may be disposed in a shape curved along an outer periphery of the first bank BNK1 and an outer periphery of the third bank BNK3. The third signal line TL3 may be disposed in a shape curved along an outer periphery of the second bank BNK2 and the outer periphery of the third bank BNK3. The fifth signal line TL5 may be disposed in a shape curved along the outer periphery of the first bank BNK1. The sixth signal line TL6 may be disposed in a shape curved along the outer periphery of the second bank BNK2.

The intervals between the plurality of signal lines TL in the first direction DR1 may vary depending on the positions. For example, the intervals between the plurality of signal lines TL in the first column may be different from the intervals between the plurality of signal lines TL in the plurality of second columns. The interval between the plurality of signal lines TL between the first subpixel SP1 and the second subpixel SP2 may be smaller than the interval between the plurality of signal lines TL between the third subpixels SP3. For example, the second signal line TL2, the fifth signal line TL5, the sixth signal line TL6, and the third signal line TL3 may be sequentially disposed between the first subpixel SP1 and the second subpixel SP2. In this case, the interval between the second signal line TL2 and the fifth signal line TL5 between the first subpixel SP1 and the second subpixel SP2, the interval between the fifth signal line TL5 and the sixth signal line TL6, and the interval between the sixth signal line TL6 and the third signal line TL3 may be smaller than the interval between the second signal line TL2 and the fifth signal line TL5 disposed between the third subpixels SP3, the interval between the fifth signal line TL5 and the sixth signal line TL6, and the interval between the sixth signal line TL6 and the third signal line TL3.

Meanwhile, the interval between the signal lines TL adjacent to each other in the first direction DR1 may be smaller than the length of the short axis of the bank BNK. For example, a shortest distance between the first signal line TL1 and the second signal line TL2 may be shorter than the length of the short axis of the first bank BNK1. A shortest distance between the third signal line TL3 and the fourth signal line TL4 may be shorter than the length of the short axis of the second bank BNK2. A shortest distance between the fifth signal line TL5 and the sixth signal line TL6 may be shorter than the length of the short axis of the third bank BNK3.

Some of the plurality of signal lines TL may be integrated in the second direction DR2. For example, the first signal line TL1 and the fourth signal line TL4 may be integrated in the second direction DR2.

In addition, the first signal line TL1 and the fourth signal line TL4 may be respectively connected to the plurality of first electrodes CE1 extending in the first direction DR1.

The first signal line TL1 may be connected to the plurality of first subpixels SP1 through the first-first electrodes CE1-1 extending in the first direction DR1. For example, the first signal line TL1 may be electrically connected to one of the pair of first subpixels SP1, e.g., the first-first electrode CE1-1 of the first-first subpixel SP1a.

The fourth signal line TL4 may be connected to the plurality of second subpixels SP2 through the plurality of first-second electrodes CE1-2 extending in the first direction DR1. The fourth signal line TL4 may be electrically connected to the remaining one of the pair of second subpixels SP2, e.g., the first-second electrode CE1-2 of the second-second subpixel SP2b.

Some of the plurality of signal lines TL may include a plurality of lines disposed to be spaced apart from one another with the plurality of banks BNK interposed therebetween. For example, the plurality of second signal lines TL2 may include a plurality of lines disposed alternately with the plurality of first banks BNK1. The plurality of third signal lines TL3 may include a plurality of lines disposed alternately with the plurality of second banks BNK2. The plurality of fifth signal lines TL5 and the plurality of sixth signal lines TL6 may include a plurality of lines disposed alternately with the plurality of third banks BNK3 in the second direction DR2.

In addition, the plurality of lines of the second signal line TL2, the third signal line TL3, the fourth signal line TL4, the fifth signal line TL5, and the sixth signal line TL6 may extend in the first direction DR1 and the second direction DR2 and be connected to the plurality of subpixels.

The plurality of second signal lines TL2 may be connected to the plurality of first subpixels SP1 through the plurality of first-first electrodes CE1-1 extending in the first direction DR1 and the second direction DR2. The second signal line TL2 may be electrically connected to the remaining one of the pair of first subpixels SP1, e.g., the first-first electrode CE1-1 of the first-second subpixel SP1b. One end of each of the plurality of lines of the second signal line TL2 may be connected to the first-first electrode CE1-1 extending in the first direction DR1 on one first bank BNK1, and the other end of each of the plurality of lines of the second signal line TL2 may be connected to the first-first electrode CE1-1 extending in the second direction DR2 on the first bank BNK1 adjacent in the second direction DR2.

The plurality of third signal lines TL3 may be connected to the plurality of second subpixels SP2 through the plurality of first-second electrodes CE1-2 extending in the first direction DR1 and the second direction DR2. For example, the third signal line TL3 may be electrically connected to one of the pair of second subpixels SP2, e.g., the first-second electrode CE1-2 of the second-first subpixel SP2a. One end of each of the plurality of lines of the third signal line TL3 may be connected to the first-second electrode CE1-2 extending in the first direction DR1 on one second bank BNK2, and the other end of each of the plurality of lines of the third signal line TL3 may be connected to the first-second electrode CE1-2 extending in the second direction DR2 on the second bank BNK2 adjacent in the second direction DR2.

The plurality of fifth signal lines TL5 may be connected to the plurality of third subpixels SP3 through the plurality of first-third electrodes CE1-3 extending in the second direction DR2. For example, the fifth signal line TL5 may be electrically connected to one of the pair of third subpixels SP3, e.g., the first-third electrode CE1-3 of the third-first subpixel SP3a. For example, one end of each of the plurality of lines of the fifth signal line TL5 may be connected to the first-third electrode CE1-3 extending in the second direction DR2 on one third bank BNK3, and the other end of each of the plurality of lines of the fifth signal line TL5 may be connected to the first-third electrode CE1-3 extending in the second direction DR2 on the third bank BNK3 adjacent in the second direction DR2.

The plurality of sixth signal lines TL6 may be connected to the plurality of third subpixels SP3 through the plurality of first-third electrodes CE1-3 extending in the second direction DR2. For example, the sixth signal line TL6 may be connected to the remaining one of the pair of third subpixels SP3. For example, one end of each of the plurality of lines of the sixth signal line TL6 may be connected to the first-third electrode CE1-3 extending in the second direction DR2 on one third bank BNK3, and the other end of each of the plurality of lines of the sixth signal line TL6 may be connected to the first-third electrode CE1-3 extending in the second direction DR2 on the third bank BNK3 adjacent in the second direction DR2.

The plurality of banks BNK may include the plurality of first banks BNK1 and the plurality of second banks BNK2 alternately disposed in the first direction DR1 in the first column, and the third banks BNK3 disposed in the first direction DR1 in the second column.

Meanwhile, the distance between the first bank BNK1 and the second bank BNK2 may be shorter than the length of the third bank BNK3 in the first direction DR1. For example, the distance between the first bank BNK1 and the second bank BNK2 may be shorter than the length of the long axis of the third bank BNK.

The plurality of first electrodes CE1 may be disposed on the top surfaces and the side surfaces of the plurality of banks BNK. The plurality of first electrodes CE1 may include the plurality of first-first electrodes CE1-1 disposed on the plurality of first banks BNK1, the plurality of first-second electrodes CE1-2 disposed on the plurality of second banks BNK2, and the plurality of first-third electrodes CE1-3 disposed on the plurality of third banks BNK3.

The plurality of first electrodes CE1 may include the first electrodes CE1 extending in different directions on the plurality of banks BNK.

For example, the plurality of first-first electrodes CE1-1 may extend in the first direction DR1 and/or the second direction DR2 on the plurality of first banks BNK1. For example, the first-first electrode CE1-1 connected to the first-first subpixel SP1a may extend in the first direction DR1 on the first bank BNK1 and be electrically connected to the first signal line TL1. In addition, the first-first electrode CE1-1 connected to the first-first subpixel SP1a may extend in the first direction DR1 on the first bank BNK1 and cover only one side surface of each of the plurality of first banks BNK1. The first-first electrode CE1-1 connected to the first-second subpixel SP1b may extend in the first direction DR1 and the second direction DR2 on the first bank BNK1 and be electrically connected to the first signal line TL1. In addition, the first-first electrode CE1-1 connected to the first-second subpixel SP1b may extend in the first direction DR1 and the second direction DR2 on the first bank BNK1 and cover a plurality of side surfaces of the plurality of first banks BNK1.

The plurality of first-second electrodes CE1-2 may extend in the first direction DR1 and/or the second direction DR2 on the plurality of second banks BNK2. For example, the first-second electrode CE1-2 connected to the second-first subpixel SP2a may extend in the first direction DR1 and the second direction DR2 on the second bank BNK2 and be electrically connected to the first signal line TL1. In addition, the first-second electrode CE1-2 connected to the second-first subpixel SP2a may extend in the first direction DR1 and the second direction DR2 on the second bank BNK2 and cover a plurality of side surfaces of the plurality of second banks BNK2. The first-second electrode CE1-2 connected to the second-second subpixel SP2b may extend in the first direction DR1 on the second bank BNK2 and be electrically connected to the first signal line TL1. In addition, the first-second electrode CE1-2 connected to the second-second subpixel SP2b may extend in the first direction DR1 on the second bank BNK2 and cover only one side surface of each of the plurality of second banks BNK2.

The plurality of first-third electrodes CE1-3 may extend in the second direction DR2 on the plurality of third banks BNK3. For example, the first-third electrode CE1-3 connected to the third-first subpixel SP3a may extend in the second direction DR2 on the third bank BNK3 and be electrically connected to the fifth signal line TL5. In addition, the first-third electrode CE1-3 connected to the third-first subpixel SP3a may extend in the second direction DR2 on the third bank BNK3 and cover a plurality of side surfaces of the plurality of third banks BNK3. The first-third electrode CE1-3 connected to the third-second subpixel SP3b may extend in the second direction DR2 on the third bank BNK3 and be electrically connected to the sixth signal line TL6. In addition, the first-third electrode CE1-3 connected to the third-second subpixel SP3b may extend in the second direction DR2 on the third bank BNK3 and cover the plurality of side surfaces of the plurality of third banks BNK3.

Meanwhile, the plurality of first electrodes CE1 may be integrated with the plurality of signal lines TL. For example, the plurality of first-first electrodes CE1-1 may be made of the same or substantially same electrically conductive material as the first signal line TL1 and the second signal line TL2. The plurality of first-second electrodes CE1-2 may be made of the same or substantially same electrically conductive material as the third signal line TL3 and the fourth signal line TL4. The plurality of first-third electrodes CE1-3 may be made of the same or substantially same electrically conductive material as the fifth signal line TL5 and the sixth signal line TL6. However, the embodiments of the present specification are not limited thereto.

In a display apparatus 2000 according to another embodiment of the present specification, in one pixel PX, the first subpixels SP1 and the second subpixels SP2 are disposed in the first direction DR1 in the first column, and the third subpixels SP3 are disposed in the second column. Therefore, the pitch of the pixel PX in the first direction DR1 may be reduced, such that a larger number of pixels PX may be disposed when the area remains the same or substantially same, thereby implementing the high-resolution display apparatus.

In the display apparatus 2000 according to another embodiment of the present specification, the pair of micro-LEDs ED disposed on one bank BNK are disposed in different directions. For example, the first-first micro-LED 130a and the first-second micro-LED 130b are disposed in the second direction DR2 on the first bank BNK1, the second-first micro-LED 140a and the second-second micro-LED 140b are disposed in the second direction DR2 on the second bank BNK2, and the third-first micro-LED 150a and the third-second micro-LED 150b are disposed in the first direction DR1 on the third bank BNK3. Therefore, the pitch of the pixel PX in the second direction DR2 may be reduced, such that a larger number of pixels PX may be disposed when the area remains the same or substantially same, thereby implementing the high-resolution display apparatus.

The third bank is disposed between the second signal line, which is connected to the adjacent first subpixel, and the fifth signal line connected to the third subpixel. Therefore, in case that all the plurality of signal lines are disposed in straight, a minimum interval between the second signal line and the fifth signal line may correspond to the length of the long axis of the third bank. Therefore, in case that all the plurality of signal lines are disposed straight, it may be difficult to make the interval between the first subpixel and the second subpixel in the first direction shorter than the length of the long axis of the third bank.

In the display apparatus 2000 according to another embodiment of the present specification, the plurality of signal lines TL may be disposed in shapes curved in the first direction DR1 and the second direction DR2, thereby reducing the intervals between the plurality of banks BNK. For example, the second signal line TL2, the third signal line TL3, the fifth signal line TL5, and the sixth signal line TL6 may each be disposed in a shape curved along the outer periphery of each of the plurality of banks BNK. Therefore, the interval between the plurality of signal lines TL between the first subpixel SP1 and the second subpixel SP2 may be smaller than the interval between the plurality of signal lines TL between the third subpixels SP3. For example, the minimum interval between the second signal line TL2 and the fifth signal line TL5 between the first subpixel SP1 and the second subpixel SP2 may be smaller than the length of the long axis of the third bank BNK3. Therefore, in the display apparatus 2000 according to another embodiment of the present specification, the distance between the first bank BNK1 and the second bank BNK2 may be shorter than the length of the long axis of the third bank BNK3, and the pitch of the pixel PX in the first direction DR1 may be reduced.

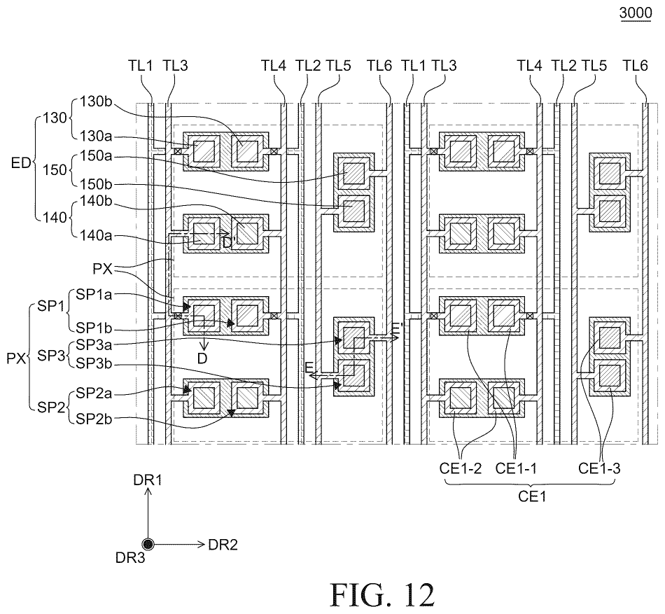

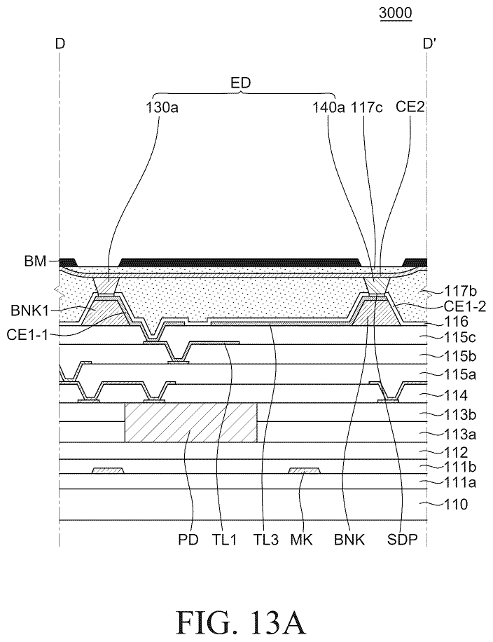

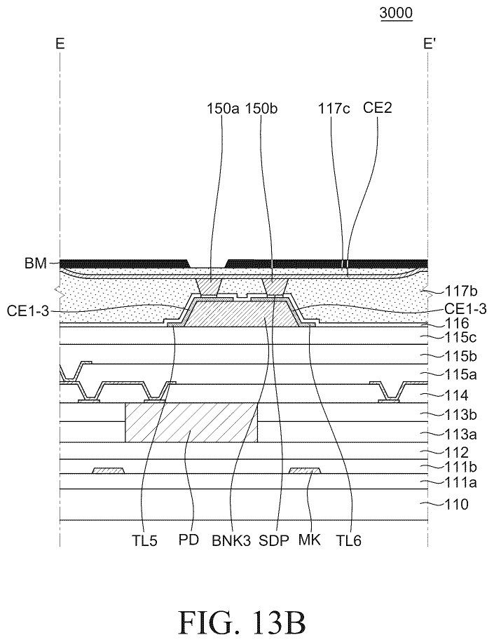

FIG. 12 is a top plan view of a display apparatus according to still another embodiment of the present specification. FIG. 13A is a cross-sectional view taken along line D-D′ in FIG. 12 according to an embodiment of the present specification. FIG. 13B is a cross-sectional view taken along line E-E′ in FIG. 12 according to an embodiment of the present specification. The display apparatus in FIGS. 12 to 13B is substantially identical in configuration to the display apparatus 1000 in FIG. 11, except for the plurality of signal lines TL and the plurality of first electrodes CE1. Therefore, repeated descriptions of the identical components will be omitted.

With reference to FIG. 12, the plurality of signal lines TL may be disposed in areas between the plurality of subpixels.

The plurality of signal lines TL may include the first signal lines TL1, the second signal lines TL2, the third signal lines TL3, the fourth signal lines TL4, the fifth signal lines TL5, and the sixth signal lines TL6.

The plurality of signal lines TL may extend in the first direction DR1. For example, the plurality of signal lines TL may be disposed straight in the first direction DR1.

The plurality of signal lines TL may be disposed to be spaced apart from one another in the second direction DR2. For example, the first signal line TL1 and the second signal line TL2 may be disposed adjacent to each other with the first subpixel SP1 interposed therebetween in the second direction DR2. The third signal line TL3 and the fourth signal line TL4 may be disposed adjacent to each other with the second subpixel SP2 interposed therebetween in the second direction DR2. The fifth signal line TL5 and the sixth signal line TL6 may be disposed adjacent to each other with the third subpixel SP3 interposed therebetween in the second direction DR2.

The first signal line TL1 and the second signal line TL2 may be connected to the plurality of first subpixels SP1 among the plurality of subpixels disposed in the first direction DR1 in the first column. The third signal line TL3 and the fourth signal line TL4 may be connected to the plurality of second subpixels SP2 among the plurality of subpixels disposed in the first direction DR1 in the first column. The fifth signal line TL5 and the sixth signal line TL6 may be connected to the plurality of third subpixels SP3 among the plurality of subpixels disposed in the first direction DR1 in the second column.

The plurality of signal lines TL may include the signal lines TL disposed on different layers. With reference to FIGS. 13A and 13B together, the first signal line TL1 and the second signal line TL2 may be disposed on the second insulation layer 115b, and the third signal line TL3, the fourth signal line TL4, the fifth signal line TL5, and the sixth signal line TL6 may be disposed on the third insulation layer 115c.

Meanwhile, FIG. 12 illustrates that the first signal line TL1, the third signal line TL3, the fourth signal line TL4, the second signal line TL2, the fifth signal line TL5, and the sixth signal line TL6 are sequentially disposed in the second direction DR2. However, the embodiments of the present specification are not limited thereto. For example, the first signal line TL1 may be disposed to overlap the third signal line TL3, and the second signal line TL2 may be disposed to overlap the fourth signal line TL4. In another example, the third signal line TL3, the first signal line TL1, the second signal line TL2, the fourth signal line TL4, the fifth signal line TL5, and the sixth signal line TL6 may be sequentially disposed in the second direction DR2.

With reference to FIGS. 12 to 13B, the plurality of signal lines TL may be respectively connected to the plurality of first electrodes CE1 extending in the second direction DR2. For example, the plurality of first signal lines TL1 and the plurality of second signal lines TL2 may be respectively connected to the plurality of first subpixels SP1 through the plurality of first-first electrodes CE1-1 extending in the second direction DR2. The plurality of third signal lines TL3 and the plurality of fourth signal lines TL4 may be respectively connected to the plurality of second subpixels SP2 through the plurality of first-second electrodes CE1-2 extending in the second direction DR2. The plurality of fifth signal lines TL5 and the plurality of sixth signal lines TL6 may be respectively connected to the plurality of third subpixels SP3 through the plurality of first-third electrodes CE1-3 extending in the second direction DR2.

The plurality of first electrodes CE1 may be disposed in the plurality of subpixels. The plurality of first electrodes CE1 may include the plurality of first-first electrodes CE1-1, the plurality of first-second electrodes CE1-2, and the plurality of first-third electrodes CE1-3.

The plurality of first electrodes CE1 may be disposed on the plurality of banks BNK. The plurality of first-first electrodes CE1-1 may be disposed on the plurality of first banks BNK1. The plurality of first-second electrodes CE1-2 may be disposed on the plurality of second banks BNK2. The plurality of first-third electrodes CE1-3 may be disposed on the plurality of third banks BNK3.

The plurality of first electrodes CE1 may extend in the second direction DR2 on the plurality of banks BNK. The plurality of first-first electrodes CE1-1 may extend in the second direction DR2 on the plurality of first banks BNK1. The plurality of first-second electrodes CE1-2 may extend in the second direction DR2 on the plurality of second banks BNK2. The plurality of first-third electrodes CE1-3 may extend in the second direction DR2 on the plurality of third banks BNK3.

Some of the plurality of first electrodes CE1 may be integrated and disposed on the same layer as the plurality of signal lines TL. For example, the plurality of first-second electrodes CE1-2 may extend on the third insulation layer 115c on the second bank BNK2 and be integrated with the third signal line TL3 and the fourth signal line TL4. The plurality of first-third electrodes CE1-3 may extend on the third insulation layer 115c on the third bank BNK3 and be integrated with the fifth signal line TL5 and the sixth signal line TL6.

Some of the plurality of first electrodes CE1 may be disposed on layers different from layers of the plurality of signal lines TL and connected to the plurality of signal lines TL through the contact holes. For example, the plurality of first-first electrodes CE1-1 may be disposed on the third insulation layer 115c on the first bank BNK1. The plurality of first-first electrodes CE1-1 may be connected to the first signal line TL1 and the second signal line TL2, which are disposed below the third insulation layer 115c, through the contact hole disposed in the third insulation layer 115c.

In a display apparatus 3000 according to still another embodiment of the present specification, in one pixel PX, the first subpixels SP1 and the second subpixels SP2 are disposed in the first direction DR1 in the first column, and the third subpixels SP3 are disposed in the second column. Therefore, the pitch of the pixel PX in the first direction DR1 may be reduced, such that a larger number of pixels PX may be disposed when the area remains the same or substantially same, thereby implementing the high-resolution display apparatus.

In the display apparatus 3000 according to still another embodiment of the present specification, the pair of micro-LEDs ED disposed on one bank BNK are disposed in different directions. For example, the first-first micro-LED 130a and the first-second micro-LED 130b are disposed in the second direction DR2 on the first bank BNK1, the second-first micro-LED 140a and the second-second micro-LED 140b are disposed in the second direction DR2 on the second bank BNK2, and the third-first micro-LED 150a and the third-second micro-LED 150b are disposed in the first direction DR1 on the third bank BNK3. Therefore, the pitch of the pixel PX in the second direction DR2 may be reduced, such that a larger number of pixels PX may be disposed when the area remains the same or substantially same, thereby implementing the high-resolution display apparatus.

In the display apparatus 3000 according to still another embodiment of the present specification, the plurality of signal lines TL may extend in the first direction DR1 and disposed to be spaced apart from one another in the second direction DR2. Therefore, the plurality of signal lines TL may not be disposed between the first subpixel SP1 and the second subpixel SP2 disposed in the first direction DR1. Therefore, in the display apparatus 3000 according to still another embodiment of the present specification, the interval between the first bank BNK1 and the second bank BNK2 may be reduced without considering the plurality of signal lines TL. Therefore, the interval between the first bank BNK1 and the second bank BNK2 may be smaller than the length of the long axis of the third bank BNK, such that the pitch of the pixel PX in the first direction DR1 may be reduced.

The plurality of banks may be disposed to be spaced apart from one another at predetermined intervals in order to suppress a short circuit in the signal line between the adjacent banks. For example, in case that the first subpixel and the second subpixel are sequentially disposed in the first column and the third subpixel is disposed in the second column, the signal lines respectively connected to the first subpixel, the second subpixel, and the third subpixel may be disposed between the adjacent banks. That is, three types of signal lines, to which different signals are applied, may be disposed between the adjacent banks. Therefore, it may be difficult to reduce the interval between the banks in case that all the signal line connected to the first subpixel, the signal line connected to the second subpixel, and the signal line connected to the third subpixel are disposed on the same layer.

In the display apparatus 3000 according to still another embodiment of the present specification, the plurality of signal lines TL, to which different signals are applied, may be disposed on different layers, thereby reducing the intervals between the plurality of banks BNK. For example, the first signal line TL1 connected to the first subpixel SP1 may be disposed on the second insulation layer 115b, and the third signal line TL3, the fourth signal line TL4, the fifth signal line TL5, and the sixth signal line TL6 may be disposed on the third insulation layer 115c. Therefore, only the fourth signal line TL4 and the fifth signal line TL5 may be disposed between the second bank BNK2 and the third bank BNK3 on the third insulation layer 115c. Therefore, the intervals between the plurality of banks BNK1 may be reduced and the pitch of the pixel PX may be reduced in comparison with the case in which all the plurality of signal lines TL are disposed on the same layer.

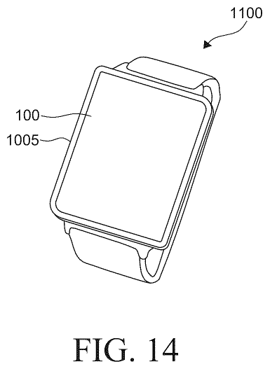

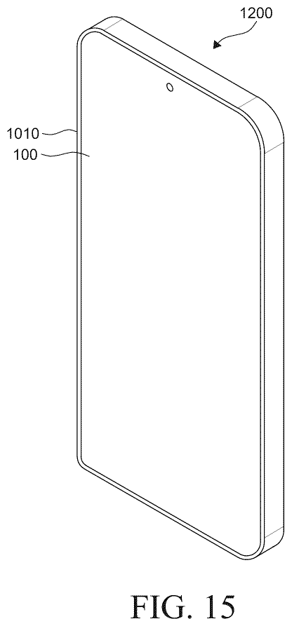

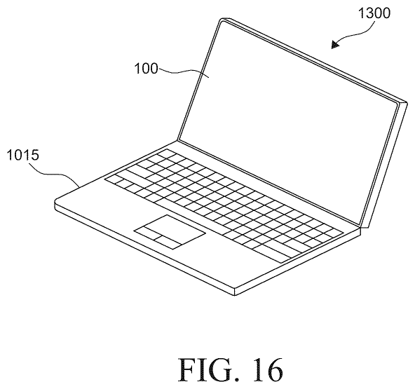

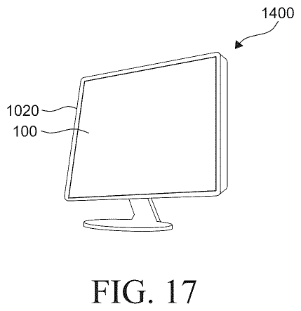

FIGS. 14 to 17 are views illustrating devices to which a display apparatus according to exemplary embodiments of the present disclosure is applied.

Referring to FIGS. 14 to 17, the display apparatus 1000 according to the exemplary embodiments of the present disclosure may be included in various devices or electronic devices. For example, referring to FIGS. 14 to 17, various electronic devices may include a wearable device 1100, a mobile device 1200, a laptop 1300, and a monitor or TV 1400, but the exemplary embodiments of the present disclosure are not limited thereto.

Each of the wearable device 1100, the mobile device 1200, the laptop 1300, and a monitor or TV 1400 may respectively include case units 1005, 1010, 1015, and 1020 and display panel 100 and the display apparatus 1000 according to the exemplary embodiments of the present disclosure which have been described in FIGS. 1 to 13B, respectively.

For example, the display apparatus 1000 according to the exemplary embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic note, an electronic book, a portable multimedia player (PMP), a personal digital assistant (PDA), an MP3 player, a mobile medical apparatus, a desktop personal computer (PC), a laptop PC, a netbook computer, a workstation, a navigation, a display apparatus for a vehicle, a theatrical display apparatus, a television, a wallpaper device, a signage device, a game device, a laptop, a monitor, a camera, a camcorder, and a consumer electronics device.

The exemplary embodiments of the present disclosure can also be described as follows:

According to an aspect of the present disclosure, there is provided a display apparatus. The display apparatus comprises a substrate, comprising a display area comprising a plurality of pixels, and a non-display area, one or more pixel drive circuits disposed on the substrate, a plurality of insulation layers disposed on the substrate, a plurality of banks on which the plurality of pixels is disposed on the plurality of insulation layers and a plurality of micro-LEDs disposed on the plurality of banks, wherein the plurality of pixels each comprise first subpixel and second subpixel sequentially disposed in a first direction in a first column and a third subpixel disposed in a second column.

The first subpixel may comprise a first-first subpixel and a first-second subpixel arranged in a second direction, the second subpixel may comprise a second-first subpixel and a second-second subpixel arranged in the second direction, and the third subpixel may comprise a third-first subpixel and a third-second subpixel arranged in the first direction.

Some of the plurality of banks may be different in long axis directions from some of the other banks.

The plurality of banks may comprise a first bank on which the first subpixel is disposed, a second bank on which the second subpixel is disposed and a third bank on which the third subpixel is disposed, wherein the first bank and the second bank each may have a long axis in a second direction, and wherein the third bank may have a long axis in the first direction.

The display apparatus may further comprise a plurality of signal lines connected to the plurality of pixels, wherein the plurality of signal lines may comprise a first signal line and a second signal line connected to the first subpixel, a third signal line and a fourth signal line connected to the second subpixel, and a fifth signal line and a sixth signal line connected to the third subpixel, and wherein the first signal line, the second signal line, the fifth signal line, the sixth signal line, the third signal line, and the fourth signal line may be sequentially disposed in the first direction.

The display apparatus may further comprise a plurality of first electrodes connected to the plurality of micro-LEDs on the plurality of banks, wherein the plurality of first electrodes may comprise a plurality of first-first electrodes extending in the first direction on the first bank, a plurality of first-second electrodes extending in the first direction on the second bank and a plurality of first-third electrodes extending in the second direction on the third bank.

The fifth and sixth signal lines each may comprise a plurality of lines disposed alternately with the third bank in the second direction, the plurality of first-third electrodes may extend on the third bank and cover side surfaces of the third banks that face one another in the second direction, and the plurality of lines of the fifth signal line and the plurality of lines of the sixth signal line may be connected to two opposite ends of each of the plurality of first-third electrodes.

The first signal line and the second signal line may be disposed adjacent to each other with the first subpixel interposed therebetween in the first direction, and the third signal line and the fourth signal line may be disposed adjacent to each other with the second subpixel interposed therebetween in the first direction.

The plurality of signal lines may be each disposed straight in the second direction.

The second signal line may comprise a plurality of lines disposed to be spaced apart from one another with the first bank interposed therebetween, the plurality of signal lines of the second signal line may extend in the first direction and the second direction, the third signal line may comprise a plurality of lines disposed to be spaced apart from one another with the second bank interposed therebetween, and the plurality of signal lines of the third signal line may extend in the first direction and the second direction.

The display apparatus may further comprise a plurality of first electrodes connected to the plurality of micro-LEDs on the plurality of banks, wherein the plurality of first electrodes may comprise a plurality of first-first electrodes extending in the first direction and the second direction on the first bank and configured to cover a side surface of the first bank, a plurality of first-second electrodes extending in the first direction and the second direction on the second bank and configured to cover a side surface of the second bank, and a plurality of first-third electrodes extending in the second direction on the third bank and configured to cover a side surface of the third bank, wherein the plurality of lines of the second signal line may be electrically connected to the plurality of first-first electrodes, and wherein the plurality of lines of the third signal line may be electrically connected to the plurality of first-second electrodes.

The first signal line and the fourth signal line may be disposed straight in the second direction.

A shortest distance between the first signal line and the second signal line may be shorter than a length of a short axis of the first bank, a shortest distance between the third signal line and the fourth signal line may be shorter than a length of a short axis of the second bank, and a shortest distance between the fifth signal line and the sixth signal line may be shorter than a length of a short axis of the third bank.

A distance between the first bank and the second bank in the first direction may be shorter than a length of the long axis of the third bank.

The display apparatus may further comprise a plurality of signal lines connected to the plurality of pixels and extending in the first direction, wherein the plurality of signal lines may comprise signal lines disposed on different layers.

The signal line connected to the second subpixel and the signal line connected to the third subpixel may be disposed on the signal line connected to the first subpixel.

The display apparatus may further comprise a plurality of first electrodes connected to the plurality of micro-LEDs on the plurality of banks, wherein the plurality of first electrodes may comprise a plurality of first-first electrodes extending in the second direction on the first bank, a plurality of first-second electrodes extending in the second direction on the second bank, and a plurality of first-third electrodes extending in the second direction on the third bank.

The signal line connected to the second subpixel may be integrated as the plurality of first-second electrodes on a same layer, and the signal line connected to the third subpixel may be integrated as the plurality of first-third electrodes on the same layer.

The signal line connected to the first subpixel may be electrically connected to the plurality of first-first electrodes through a contact hole.

The first subpixel, the second subpixel, and the third subpixel may emit light beams with different colors.

The plurality of micro-LEDs each may comprise an anode electrode, a first semiconductor layer disposed on the anode electrode, an active layer disposed on the first semiconductor layer, a second semiconductor layer disposed on the active layer, and a cathode electrode disposed on the second semiconductor layer.

The display apparatus may further comprise a first electrode disposed below the plurality of micro-LEDs and configured to electrically connect the pixel drive circuit and the anode electrode of each of the plurality of micro-LEDs, and a solder pattern disposed between the first electrode and the anode electrode, wherein the first electrode and the anode electrode may be electrically connected by eutectic bonding using the solder pattern.

According to another aspect of the present disclosure, there is provided a display apparatus. The display apparatus comprises a substrate, one or more pixel drive circuits disposed on the substrate, a plurality of insulation layers disposed on the pixel drive circuit, a plurality of banks disposed on the plurality of insulation layers and a plurality of micro-LEDs disposed on the plurality of banks and electrically connected to the pixel drive circuit, wherein some of the plurality of banks are different in long axis directions from some of the other banks.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure

What is claimed is:

1. A display apparatus comprising:
a substrate comprising a display area and a non-display area, the display area comprising a plurality of pixels;
one or more pixel drive circuits on the substrate;
a plurality of insulation layers on the substrate;
a plurality of banks on which the plurality of pixels are disposed on the plurality of insulation layers; and
a plurality of micro-light emitting diodes (LEDs) on the plurality of banks, wherein each of the plurality of pixels comprise:
a first subpixel and a second subpixel sequentially disposed in a first direction in a first column; and
a third subpixel disposed in a second column.

2. The display apparatus of claim 1, wherein the first subpixel comprises a first-first subpixel and a first-second subpixel arranged in a second direction, the second subpixel comprises a second-first subpixel and a second-second subpixel arranged in the second direction, and the third subpixel comprises a third-first subpixel and a third-second subpixel arranged in the first direction.

3. The display apparatus of claim 1, wherein the plurality of banks comprises:
a first bank on which the first subpixel is disposed;
a second bank on which the second subpixel is disposed; and
a third bank on which the third subpixel is disposed,
wherein the first bank and the second bank each have a long axis in a second direction and the third bank has a long axis in the first direction.

4. The display apparatus of claim 3, further comprising:
a plurality of signal lines connected to the plurality of pixels, the plurality of signal lines comprising:
a first signal line and a second signal line connected to the first subpixel;
a third signal line and a fourth signal line connected to the second subpixel; and
a fifth signal line and a sixth signal line connected to the third subpixel, and
wherein the first signal line, the second signal line, the fifth signal line, the sixth signal line, the third signal line, and the fourth signal line are sequentially disposed in the first direction.

5. The display apparatus of claim 4, further comprising:
a plurality of first electrodes connected to the plurality of micro-LEDs on the plurality of banks, the plurality of first electrodes comprising:
a plurality of first-first electrodes extending in the first direction on the first bank;
a plurality of first-second electrodes extending in the first direction on the second bank; and
a plurality of first-third electrodes extending in the second direction on the third bank.

6. The display apparatus of claim 5, wherein the fifth signal line and the sixth signal line each comprises a plurality of lines disposed alternately with the third bank in the second direction, the plurality of first-third electrodes extend on the third bank and cover side surfaces of the third bank and face one another in the second direction, and two opposite ends of each of the plurality of lines of the fifth signal line and the plurality of lines of the sixth signal line are connected to two opposite ends of each of the plurality of first-third electrodes, respectively.

7. The display apparatus of claim 5, wherein the first signal line and the second signal line are adjacent to each other with the first subpixel interposed between the first signal line and the second signal line in the first direction, and the third signal line and the fourth signal line are disposed adjacent to each other with the second subpixel interposed between the third signal line and the fourth signal line in the first direction.

8. The display apparatus of claim 4, wherein each of the plurality of signal lines is disposed straight in the second direction.

9. The display apparatus of claim 4, wherein the second signal line comprises a plurality of lines that are spaced apart from one another with the first bank interposed therebetween, the plurality of signal lines of the second signal line extend in the first direction and the second direction, the third signal line comprises a plurality of lines that are spaced apart from one another with the second bank interposed therebetween, and the plurality of signal lines of the third signal line extend in the first direction and the second direction.

10. The display apparatus of claim 9, further comprising:
a plurality of first electrodes connected to the plurality of micro-LEDs on the plurality of banks, the plurality of first electrodes comprising:
a plurality of first-first electrodes extending in the first direction and the second direction on the first bank, the plurality of first-first electrodes covering a side surface of the first bank;
a plurality of first-second electrodes extending in the first direction and the second direction on the second bank, the plurality of first-second electrodes covering a side surface of the second bank; and
a plurality of first-third electrodes extending in the second direction on the third bank, the plurality of first-third electrodes covering a side surface of the third bank,
wherein the plurality of lines of the second signal line are electrically connected to the plurality of first-first electrodes, and
wherein the plurality of lines of the third signal line are electrically connected to the plurality of first-second electrodes.

11. The display apparatus of claim 9, wherein the first signal line and the fourth signal line are disposed straight in the second direction,
wherein a shortest distance between the first signal line and the second signal line is shorter than a length of a short axis of the first bank, a shortest distance between the third signal line and the fourth signal line is shorter than a length of a short axis of the second bank, and a shortest distance between the fifth signal line and the sixth signal line is shorter than a length of a short axis of the third bank.

12. The display apparatus of claim 9, wherein a distance between the first bank and the second bank in the first direction is shorter than a length of the long axis of the third bank.

13. The display apparatus of claim 3, further comprising:
a plurality of signal lines connected to the plurality of pixels, the plurality of signal lines extending in the first direction,
wherein the plurality of signal lines comprise signal lines disposed on different layers.

14. The display apparatus of claim 13, wherein a signal line from the plurality of signal lines that is connected to the second subpixel and a signal line from the plurality of signal lines that is connected to the third subpixel are on a signal line from the plurality of signal lines that is connected to the first subpixel.

15. The display apparatus of claim 14, further comprising:
a plurality of first electrodes connected to the plurality of micro-LEDs on the plurality of banks, the plurality of first electrodes comprising:
a plurality of first-first electrodes extending in the second direction on the first bank;
a plurality of first-second electrodes extending in the second direction on the second bank; and
a plurality of first-third electrodes extending in the second direction on the third bank.

16. The display apparatus of claim 15, wherein the signal line connected to the second subpixel is integrated as the plurality of first-second electrodes on a same layer and the signal line connected to the third subpixel is integrated as the plurality of first-third electrodes on a same layer.

17. The display apparatus of claim 15, wherein the signal line connected to the first subpixel is electrically connected to the plurality of first-first electrodes through a contact hole.

18. The display apparatus of claim 1, wherein the plurality of micro-LEDs each comprise:
an anode electrode;
a first semiconductor layer on the anode electrode;
an active layer on the first semiconductor layer;
a second semiconductor layer on the active layer; and
a cathode electrode on the second semiconductor layer.

19. The display apparatus of claim 18, further comprising:
a first electrode below the plurality of micro-LEDs, the first electrode electrically connecting the pixel drive circuit and the anode electrode of each of the plurality of micro-LEDs; and
a solder pattern between the first electrode and the anode electrode,
wherein the first electrode and the anode electrode are electrically connected using the solder pattern.

20. A display apparatus comprising:
a substrate;
one or more pixel drive circuits on the substrate;
a plurality of insulation layers on the one or more pixel drive circuits;
a plurality of banks on the plurality of insulation layers; and
a plurality of micro-light emitting diodes (LEDs) on the plurality of banks, the plurality of micro-LEDs electrically connected to the one or more pixel drive circuits,
wherein the plurality of banks comprise banks with different long axis directions.
